(19) United States
(12) Patent Application Publication
(10) Pub. No.: US 2025/0374804 A1
(43) Pub. Date: Dec. 4, 2025

(54) DISPLAY DEVICE AND METHOD FOR MANUFACTURING THE SAME

(71) Applicant: Samsung Display Co., LTD., Yongin-si, Gyeonggi-do (KR)

(72) Inventors: Keun Woo PARK, Yongin-si (KR); Min Jae KIM, Yongin-si (KR); Jae Cheol PARK, Yongin-si (KR); Gak Seok LEE, Yongin-si (KR)

(21) Appl. No.: 19/034,402

(22) Filed: Jan. 22, 2025

(30) Foreign Application Priority Data
Jun. 4, 2024 (KR) 10-2024-0072881

(51) Int. Cl. H10K 59/80; H10K 59/12; H10K 59/122; H10K 59/124

(52) U.S. Cl. CPC H10K 59/873; H10K 59/1201; H10K 59/122; H10K 59/124

(57) ABSTRACT

A display device includes a first substrate including a first support substrate including a main region including a display area including emission areas, and a non-display area around the display area, and a pad area connected to at least a portion of one side of the main region, a circuit layer above the first support substrate, a planarization layer above the circuit layer in the display area, an auxiliary residual layer in the non-display area and the pad area, extending from the planarization layer, and having a thickness less than that of the planarization layer, an element layer above the planarization layer, in the display area, and including light-emitting elements, and an encapsulation layer above the element layer, a second substrate opposing the first substrate, and a sealing layer between the first substrate and the second substrate in the non-display area to couple the first substrate to the second substrate.

### CROSS-REFERENCE TO RELATED APPLICATION

The present application claims priority to, and the benefit of, Korean Patent Application No. 10-2024-0072881, filed on Jun. 4, 2024, in the Korean Intellectual Property Office, the entire disclosure of is incorporated herein by reference.

### BACKGROUND

### 1. Field

The present disclosure relates to a display device and a method for manufacturing the same.

### 2. Description of the Related Art

With the advance of information-oriented society, more and more demands are placed on display devices for displaying images in various ways. For example, display devices are employed in various electronic devices, such as smartphones, digital cameras, laptop computers, navigation devices, and smart televisions.

The display device may be a flat panel display device, such as a liquid crystal display device, a field emission display device and a light-emitting display device. Examples of the light-emitting display device may include an organic light-emitting display device including organic light-emitting elements, an inorganic light-emitting display device including inorganic light-emitting elements, such as inorganic semiconductors, and a micro light-emitting display device including micro light-emitting elements.

The organic light-emitting display device displays an image using light-emitting elements, each including a light-emitting layer made of an organic light-emitting material. As described above, the organic light-emitting display device implements image display using a self-light-emitting element, and thus may have relatively superior performance in power consumption, response speed, luminous efficiency, luminance, and wide viewing angle compared to other display devices.

In the display device, a display surface from which light is emitted may include a display area in which an image is displayed, and a non-display area around the display area. Emission areas emitting light with respective luminances and colors may be arranged in the display area.

### SUMMARY

The display device may include a sealing layer that bonds a first substrate to a second substrate.

When the sealing layer is located on an organic material, the peeling of the sealing layer may be facilitated. As a result, the lifespan and display quality of the display device may deteriorate.

To reduce or prevent the likelihood of the above, an etching process may be performed to remove the organic material from the area contacting the sealing layer, so that there is a problem in that the streamlining of the process of manufacturing the display device is limited.

In view of the foregoing, aspects of the present disclosure provide a display device capable of reducing or preventing the likelihood of peeling of a sealing layer although an etching process to remove an organic material is not performed, and a method for manufacturing the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a first substrate including a first support substrate including a main region including a display area including emission areas arranged side by side, and a non-display area around the display area, and a pad area connected to at least a portion of one side of the main region, a circuit layer above the first support substrate, a planarization layer above the circuit layer, including an organic insulating material, and in the display area, an auxiliary residual layer in the non-display area and the pad area, extending from the planarization layer, and having a thickness that is less than that of the planarization layer, an element layer above the planarization layer, in the display area, and including light-emitting elements in the emission areas, and an encapsulation layer above the element layer, a second substrate opposing the first substrate, and a sealing layer between the first substrate and the second substrate in the non-display area to couple the first substrate to the second substrate.

The first substrate may further include a first bank in the non-display area between an edge of the display area and the sealing layer in plan view, and a second bank in the pad area, and extending parallel to one side of the main region, wherein the first bank and the sealing layer are around the display area in plan view, and wherein the first bank and the second bank are above the auxiliary residual layer.

The first substrate may further include one or more dam portions including two or more dam layers including an organic insulating material in the non-display area above the auxiliary residual layer and between the edge of the display area and the first bank in plan view, wherein the first bank and the second bank include two or more bank layers including an organic insulating material.

The element layer may include anode electrodes in the emission areas, a pixel-defining layer in a non-emission area between the emission areas, including an organic insulating material, and covering edges of the anode electrodes, a light-emitting layer above the anode electrodes and the pixel-defining layer, and a cathode electrode above the light-emitting layer.

The first bank may include a first bank layer above the auxiliary residual layer, and a second bank layer above the first bank layer, wherein the second bank includes a third bank layer above the auxiliary residual layer, and a fourth bank layer above the third bank layer, wherein the two or more dam layers include a first dam layer above the auxiliary residual layer, and a second dam layer above the first dam layer, wherein the auxiliary residual layer, the first bank layer, and the first dam layer are at a same layer as the planarization layer, and wherein the second bank layer and the second dam layer are at a same layer as the pixel-defining layer.

The circuit layer may include a buffer layer above the first support substrate, a first interlayer insulating layer above the buffer layer, and a second interlayer insulating layer above the first interlayer insulating layer, wherein the buffer layer, the first interlayer insulating layer, and the second interlayer insulating layer include an inorganic insulating material, wherein the planarization layer is above the second interlayer insulating layer, and wherein the encapsulation layer includes a first encapsulation layer above the element layer, including an inorganic insulating material, covering the one or more dam portions and the first bank, extending to the pad area, and adjacent to the second bank, a second encapsulation layer above the first encapsulation layer in an area surrounded by the one or more dam portions, and including an organic insulating material, and a third encapsulation layer covering the second encapsulation layer, including an inorganic insulating material, contacting the first encapsulation layer in a portion between an edge of the main region and the one or more dam portions in the non-display area, and contacting the first encapsulation layer in a portion between one side of the main region and the second bank in the pad area, and wherein the sealing layer is above the third encapsulation layer.

The first substrate may define a groove extending along the edge of the main region, penetrating the auxiliary residual layer, and including a portion extending along one side of the main region between the sealing layer and the second bank, wherein the first encapsulation layer contacts the second interlayer insulating layer or the first interlayer insulating layer through the groove.

The circuit layer may include light-emitting pixel drivers electrically connected to the light-emitting elements, lines electrically connected to the light-emitting pixel drivers, and extending to the non-display area and the pad area, and pads in the pad area, electrically connected to the lines, and covered by the second interlayer insulating layer and the auxiliary residual layer, wherein the circuit layer defines pad connection holes respectively defined by the pads, and penetrating the second interlayer insulating layer and the auxiliary residual layer, and wherein the second bank is between the groove and the pads in plan view.

The first substrate may further include pad extension portions overlapping the second bank, and respectively contacting the pads through the pad connection holes.

One of the pad extension portions may contact at least a portion of one of the pads.

The emission areas may include a first emission area for emitting light in a first wavelength band, a second emission area for emitting light in a second wavelength band that is lower than the first wavelength band, and a third emission area for emitting light in a third wavelength band that is lower than the second wavelength band, wherein the light-emitting elements are configured to emit light in a fourth wavelength band that is lower than the third wavelength band, wherein the first substrate further includes a color conversion layer above the encapsulation layer for converting a wavelength band of the light emitted from some of the light-emitting elements, and a color conversion capping layer covering the color conversion layer, wherein the second substrate includes a second support substrate including the main region, a color filter layer on one surface of the second support substrate and facing the color conversion layer, and a filter capping layer covering the color filter layer, wherein the color conversion layer includes a first color conversion portion in the first emission area for converting light in the fourth wavelength band into light in the first wavelength band, a second color conversion portion in the second emission area for converting light in the fourth wavelength band into light in the second wavelength band, a light-transmitting portion in the third emission area and transmitting for scattering light in the fourth wavelength band, and a partition wall among the first color conversion portion, the second color conversion portion, and the light-transmitting portion, and wherein the color filter layer includes a first filter portion in the first emission area for transmitting light in the first wavelength band, a second filter portion in the second emission area for transmitting light in the second wavelength band, and a third filter portion in the third emission area for transmitting light in the third wavelength band, and a light-blocking portion in a non-emission area between the emission areas for blocking light.

According to an aspect of the present disclosure, there is provided a method for manufacturing a display device, the method including preparing first substrates by using a mother substrate including panel areas including a main region including a display area including emission areas arranged side by side, and a non-display area around the display area, and a pad area connected to at least a portion of one side of the main region, separating the first substrates including first support substrates including portions of the mother substrate in the panel areas, preparing a second substrate, and bonding one of the first substrates to the second substrate, wherein the preparing of the first substrates includes depositing a circuit layer in the panel areas, depositing a planarization layer in the display area by partially removing an organic insulating material covering the circuit layer, depositing an auxiliary residual layer having a thickness that is less than that of the planarization layer in the non-display area and the pad area, depositing an element layer on the planarization layer, depositing an encapsulation layer on the element layer and the auxiliary residual layer, and depositing a sealing layer in the non-display area of the panel areas.

The depositing of the element layer may include depositing anode electrodes in the emission areas, depositing a pixel-defining layer covering edges of the anode electrodes in a non-emission area between the emission areas by partially removing an organic insulating material covering the anode electrodes, depositing a light-emitting layer on the anode electrodes and the pixel-defining layer, and depositing a cathode electrode on the light-emitting layer, wherein the depositing the planarization layer and the depositing the auxiliary residual layer includes depositing one or more first dam layers in the non-display area and sequentially surrounding an edge of the display area in plan view, a first bank layer in the non-display area and surrounding the one or more first dam layers in plan view, and a third bank layer having a portion surrounding remaining sides, excluding one side contacting the pad area, among edges of the main region, and a remaining portion in the pad area and surrounding one side of the main region, wherein the depositing of the pixel-defining layer includes depositing one or more second dam layers above the one or more first dam layers, a second bank layer above the first bank layer, and a fourth bank layer above the third bank layer, and wherein depositing the cathode electrode includes stacking a conductive material in a state where a first mask is above the second bank layer.

The depositing of the circuit layer may include depositing a buffer layer above the first support substrate, a first interlayer insulating layer above the buffer layer, and a second interlayer insulating layer above the first interlayer insulating layer, wherein the planarization layer is above the second interlayer insulating layer, wherein the planarization layer and the auxiliary residual layer define first anode connection holes overlapping the anode electrodes and penetrating the planarization layer, and wherein the depositing of the element layer further includes forming second anode connection holes that are continuous with the first anode connection holes and that penetrate the second interlayer insulating layer.

The depositing of the planarization layer and the auxiliary residual layer may include forming a first groove extending along an edge of the main region and penetrating the auxiliary residual layer, wherein the forming of the second anode connection holes includes forming a second groove continuous with the first groove and penetrating the second interlayer insulating layer.

The separating of the first substrates may include separating the mother substrate using a scribing line, wherein a remaining portion of the first groove, excluding a portion in the pad area, overlaps the scribing line.

The depositing of the encapsulation layer may include depositing a first encapsulation layer contacting the second interlayer insulating layer or the first interlayer insulating layer through the first groove and the second groove, and covering the element layer, the auxiliary residual layer, the one or more second dam layers, and the second bank layer by stacking an inorganic insulating material in a state where a second mask is above the fourth bank layer, depositing a second encapsulation layer surrounded by the one or more first dam layers and the one or more second dam layers in plan view by diffusing and curing an organic insulating material dropped on the first encapsulation layer of the display area, and depositing a third encapsulation layer covering the second encapsulation layer by stacking an inorganic insulating material in a state where the second mask is above the fourth bank layer.

The third encapsulation layer may contact the first encapsulation layer at the edge of the main region, wherein the sealing layer is above the third encapsulation layer.

The circuit layer may include light-emitting pixel drivers electrically connected to the anode electrodes through the first anode connection holes and the second anode connection holes, lines electrically connected to the light-emitting pixel drivers and extending to the non-display area and the pad area, and pads in the pad area, electrically connected to the lines, and covered with the second interlayer insulating layer and the auxiliary residual layer, wherein the planarization layer and the auxiliary residual layer define first pad connection holes overlapping the pads and penetrating the planarization layer, and wherein the forming the second anode connection holes includes forming second pad connection holes continuous with the first pad connection holes and penetrating the second interlayer insulating layer.

The depositing of the circuit layer may further include depositing pad extension portions overlapping the third bank layer and the fourth bank layer, wherein the pad extension portions contact the pads respectively through the first pad connection holes and the second pad connection holes, and wherein one of the pad extension portions contacts at least a portion of one of the pads.

According to an aspect of the present disclosure, there is provided an electronic device including a display device including a first substrate including a first support substrate including a main region including a display area including emission areas arranged side by side, and a non-display area around the display area, and a pad area connected to at least a portion of one side of the main region, a circuit layer above the first support substrate, a planarization layer above the circuit layer, including an organic insulating material, and in the display area, an auxiliary residual layer in the non-display area and the pad area, extending from the planarization layer, and having a thickness that is less than that of the planarization layer, an element layer above the planarization layer, in the display area, and including light-emitting elements in the emission areas, and an encapsulation layer above the element layer, a second substrate opposing the first substrate, and a sealing layer between the first substrate and the second substrate in the non-display area to couple the first substrate to the second substrate.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

Accordingly, because the sealing layer is bonded to the third encapsulation layer including an inorganic insulating material, peeling of the sealing layer may be reduced or prevented regardless of the auxiliary residual layer.

Accordingly, the auxiliary residual layer in the non-display area may be sealed by inorganic bonding between the second interlayer insulating layer or the first interlayer insulating layer and the first encapsulation layer. Accordingly, although the auxiliary residual layer of an organic insulating material is present, permeation of oxygen or moisture due to the auxiliary residual layer may be reduced.

As described above, according to embodiments, although the auxiliary residual layer is present, peeling of the sealing layer and permeation of oxygen or moisture may be reduced or prevented. Accordingly, the influence of the auxiliary residual layer on the lifespan and display quality of the display device may be reduced. Accordingly, the process of removing the auxiliary residual layer may be omitted, so that the method for manufacturing the display device may be streamlined.

However, aspects according to the embodiments of the present disclosure are not limited to those exemplified above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a plan view illustrating a display device according to embodiments;

FIG. 2 is a cross-sectional view taken along the line A-A′ of FIG. 1;

FIG. 3 is a plan view showing a display area and a circuit layer of part B illustrated in FIG. 1;

FIG. 4 is a block diagram showing the circuit layer of part B illustrated in FIG. 1;

FIG. 5 is an equivalent circuit diagram showing the light-emitting pixel driver of FIG. 4;

FIG. 6 is a cross-sectional view taken along the line C-C′ of FIG. 3;

FIG. 7 is a plan view showing the first substrate of FIG. 2;

FIG. 8 is a cross-sectional view taken along the line D-D′ of FIG. 7;

FIG. 9 is a cross-sectional view taken along the line E-E′ of FIG. 7;

FIG. 10 is an enlarged view showing part F of FIG. 7 according to other embodiments;

FIGS. 11 and 12 are cross-sectional views taken along the line E-E′ of FIG. 7 according to the embodiments of FIG. 10;

FIG. 13 is a flowchart illustrating a method for manufacturing the display device according to embodiments;

FIG. 14 is a flowchart illustrating an operation of preparing a plurality of first substrates of FIG. 13; and

FIGS. 15, 16, 17, 18, 19, 20, 21, 22, 23, 24, 25, 26, 27, 28, 29, 30, 31, 32, 33, 34, 35, 36, 37, and 38 are process diagrams illustrating some of the operations in FIGS. 13 and 14.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof.

Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure.

The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

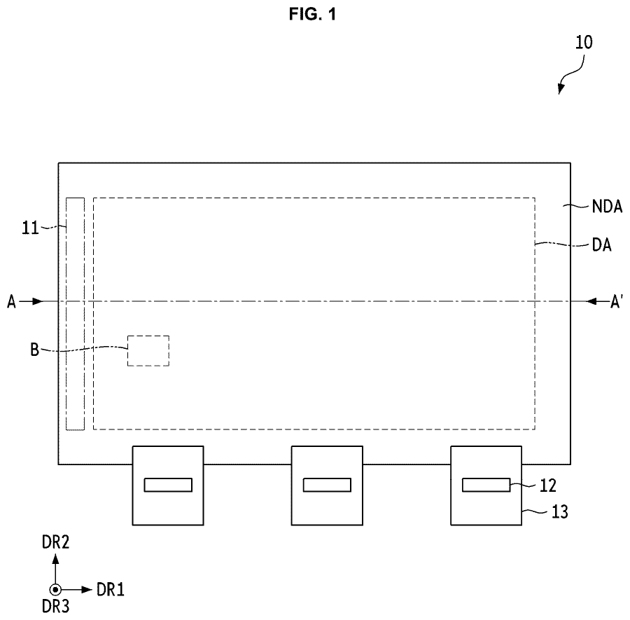

FIG. 1 is a plan view illustrating a display device according to embodiments.

Referring to FIG. 1, a display device 10 according to embodiments, which is a device for displaying a moving image or a still image, may be used as a display screen of various devices, such as a television, a laptop computer, a monitor, a billboard and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). Alternatively, in one or more embodiments, the display device 10 may be applied to a smartwatch, a watch phone, and/or a head-mounted display device (HMD) for implementing virtual reality and/or augmented reality.

The display device 10 may be a light-emitting display device, such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 10 is an organic light-emitting display device. However, the present disclosure is not limited thereto, and may be applied to a display device including an organic insulating material, an organic light-emitting material, and a metal material.

The display device 10 may be formed to be flat, but is not limited thereto. For example, the display device 10 may include a curved portion formed at left and right ends and having a constant curvature or a varying curvature. In addition, the display device 10 may be formed flexibly so that it can be curved, bent, folded, or rolled.

According to one embodiment, the display device 10 may be an organic light-emitting display device.

As illustrated in FIG. 1, the display device 10 according to embodiments may include one surface of a quadrilateral shape. However, this is merely an example, and the form of the display device 10 is not limited to that illustrated in FIG. 1. For example, the display device 10 according to embodiments may include one surface of a polygonal or circular shape in addition to a quadrilateral shape. Alternatively, at least a portion of the display device 10 may be transformed from an unfolded form to a curved, flexed, bent, folded, or rolled form.

One surface of the display device 10 may include a display area DA through which light for displaying an image is emitted, and a non-display area NDA surrounding the display area DA.

The display area DA may be located on most of the area of one surface of the display device 10.

The non-display area NDA does not emit light for displaying an image and may be in the form of a frame surrounding the display area DA. For example, the non-display area NDA may be maintained in a corresponding color, such as black.

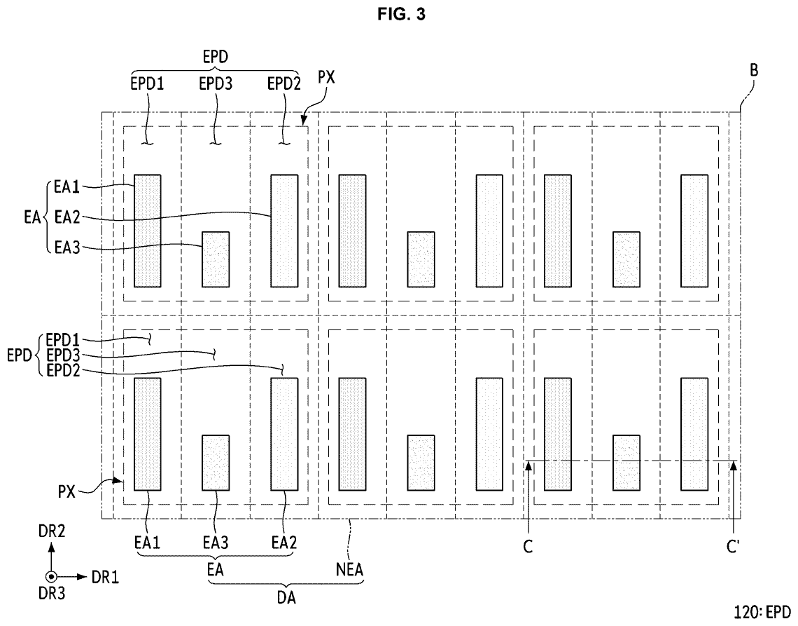

The display device 10 may include drivers 11 and 12 that transmit signals, voltage, or power to light-emitting pixel drivers EPD (see FIGS. 3, 4, and 5) located in the display area DA.

A part of the drivers 11 and 12 (e.g., the driver 11 that may be implemented with relatively simple circuits) may be located in the non-display area NDA.

Another part of the drivers 11 and 12 (e.g., the driver 12) may be prepared as integrated circuit chips, and may be mounted on a circuit board 13 electrically connected to pads in the non-display area NDA. Alternatively, the driver 12 of another part may be mounted on the pads in the non-display area NDA.

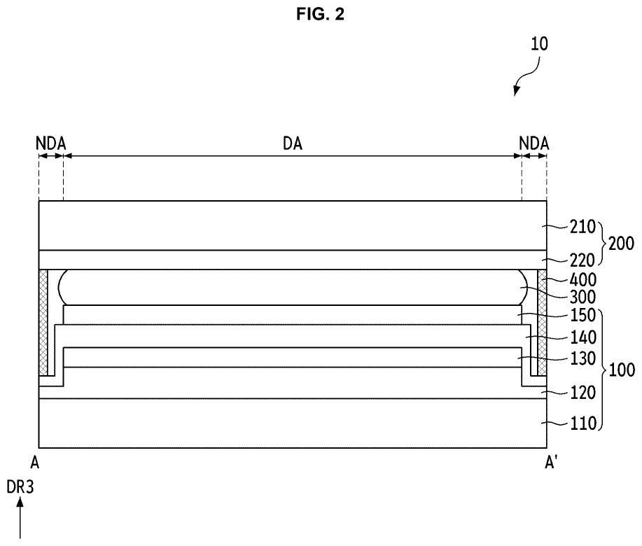

FIG. 2 is a cross-sectional view taken along the line A-A′ of FIG. 1. FIG. 3 is a plan view showing a display area and a circuit layer of part B illustrated in FIG. 1.

Referring to FIG. 2, the display device 10 according to embodiments may include a first substrate 100, and a second substrate 200 opposing the first substrate 100.

The display device 10 may further include a filling layer 300 located between the first substrate 100 and the second substrate 200. The filling layer 300 may be located at least in the display area DA, and may fill the separation space between the first substrate 100 and the second substrate 200.

The display device 10 may further include a sealing layer 400 located in the non-display area NDA for bonding the first substrate 100 and the second substrate 200 to each other.

The first substrate 100 may include a first support substrate 110, an element layer 130 located on the first support substrate 110, an encapsulation layer 140 located on the element layer 130, and a color conversion layer 150 located on the encapsulation layer 140.

The first substrate 100 may further include a circuit layer 120 located on the first support substrate 110. The element layer 130 may be located on the circuit layer 120.

The first support substrate 110 may include the display area DA through which light for displaying an image is emitted, and the non-display area NDA that is located around the display area DA and through which light is not emitted.

Referring to FIG. 3, the display area DA may include emission areas EA through which light is emitted, and a non-emission area NEA between the emission areas EA.

According to embodiments, the emission areas EA may include a first emission area EA1 that emits light in a first wavelength band, a second emission area EA2 that emits light in a second wavelength band lower than the first wavelength band, and a third emission area EA3 that emits light in a third wavelength band lower than the second wavelength band.

For example, the first wavelength band may be from about 600 nm to about 750 nm, and light in the first wavelength band may be red. The second wavelength band may be from about 480 nm to about 560 nm, and light in the second wavelength band may be green. The third wavelength band may be from about 370 nm to about 460 nm, and light in the third wavelength band may be blue.

Accordingly, a unit pixel PX that displays white light by one or more first emission areas EA1, one or more second emission areas EA2, and one or more third emission areas EA3 that are adjacent to each other among the emission areas EA may be prepared.

According to one embodiment, each of the first emission area EA1, the second emission area EA2, and the third emission area EA3 may be arranged side by side in a second direction DR2.

In addition, the third emission area EA3 may be located between the first emission area EA1 and the second emission area EA2 in a first direction DR1.

Each of the emission areas EA may be located in a shape of one of a rectangle, a triangle, a rhombus, a square, a trapezoid, a circle, and an ellipse.

According to one embodiment, the third emission area EA3 may be located to have a smaller length than the first emission area EA1 and the second emission area EA2. Accordingly, in the second direction DR2, the gap between the third emission areas EA3 may be greater than the gap between the first emission areas EA1 and the gap between the second emission areas EA2.

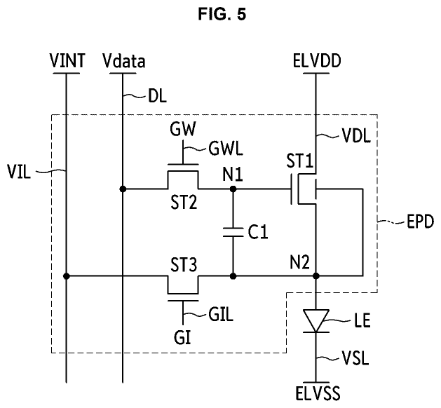

The circuit layer 120 of the first substrate 100 may include the light-emitting pixel drivers EPD arranged side by side with each other, and lines VDL, DL, VIL, GWL, and GIL (see FIG. 5) electrically connected to the light-emitting pixel drivers EPD. The lines VDL, DL, VIL, GWL, and GIL may transmit voltages or power and signals to each of the light-emitting pixel drivers EPD.

The light-emitting pixel drivers EPD may include a first light-emitting pixel driver EPD1 electrically connected to the light-emitting element LE of the first emission area EA1, a second light-emitting pixel driver EPD2 electrically connected to the light-emitting elements LE of the second emission area EA2, and a third light-emitting pixel driver EPD3 electrically connected to the light-emitting element LE of the third emission area EA3.

As illustrated in FIG. 2, the element layer 130 of the first substrate 100 may include the light-emitting elements LE (see FIG. 5) located in the emission areas EA.

According to embodiments, the light-emitting elements LE may emit light in a fourth wavelength band that is lower than the third wavelength band.

The light-emitting elements LE of the element layer 130 may be electrically connected to the light-emitting pixel drivers EPD of the circuit layer 120, respectively.

The encapsulation layer 140 may include two or more inorganic insulating layers including an inorganic insulating material, and at least one organic insulating layer located therebetween and including an organic insulating material. The encapsulation layer 140 may reduce or prevent defects in the circuit layer 120 or the element layer 130 due to foreign matters, and may reduce or prevent permeation of oxygen or moisture into the circuit layer 120 or the element layer 130.

The color conversion layer 150 may convert the wavelength band of light emitted from some of the light-emitting elements LE of the element layer 130. For example, the color conversion layer 150 may convert light emitted from the light-emitting element LE of the first emission area EA1 from the fourth wavelength band to the first wavelength band, may convert light emitted from the light-emitting element LE of the second emission area EA2 from the fourth wavelength band to the second wavelength band, and may transmit and scatter light emitted from the light-emitting element LE of the third wavelength band EA3.

The second substrate 200 may include a second support substrate 210 opposing the first support substrate 110 and including the emission areas EA and the non-emission area NEA, and a color filter layer 220 located on one surface of the second support substrate 210.

The color filter layer 220 may transmit light in a corresponding wavelength band among the light emitted from the color conversion layer 150 of the first substrate 100, through each of the emission areas EA. For example, the color filter layer 220 may transmit light in the first wavelength band through the first emission area EA1, may transmit light in the second wavelength band through the second emission area EA2, and may transmit light in the third wavelength band through the third emission area EA3.

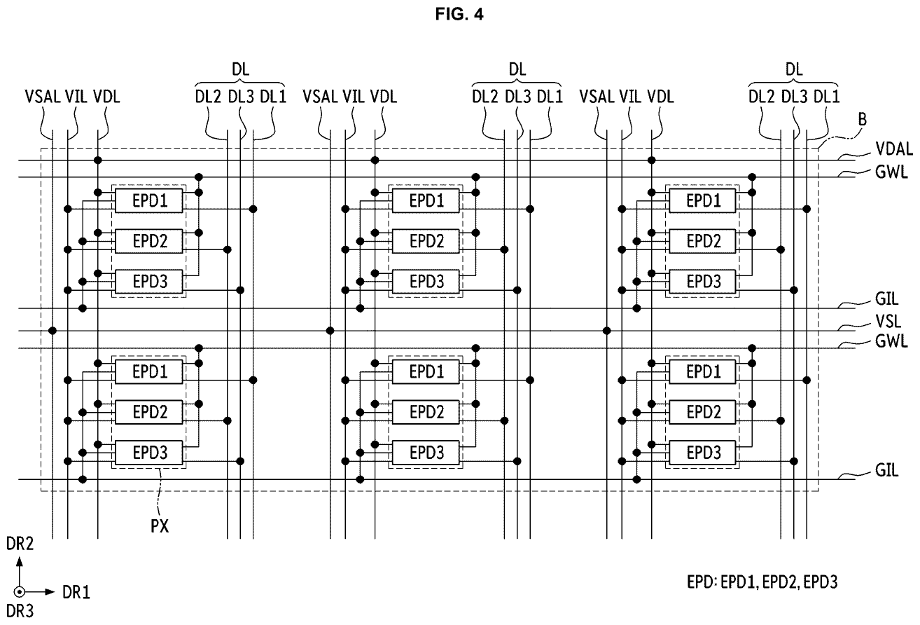

FIG. 4 is a block diagram showing the circuit layer of part B illustrated in FIG. 1. FIG. 5 is an equivalent circuit diagram showing the light-emitting pixel driver of FIG. 4.

Referring to FIG. 4, the circuit layer 120 of the first substrate 100 in the display device 10 according to embodiments includes the light-emitting pixel drivers EPD electrically connected to the light-emitting elements LE of the emission areas EA, respectively.

The light-emitting pixel drivers EPD may include the first light-emitting pixel driver EPD1 electrically connected to the light-emitting element LE of the first emission area EA1, the second light-emitting pixel driver EPD2 electrically connected to the light-emitting elements LE of the second emission area EA2, and the third light-emitting pixel driver EPD3 electrically connected to the light-emitting element LE of the third emission area EA3.

The circuit layer 120 may further include a scan write line GWL that transmits a scan write signal GW (see FIG. 5) to the light-emitting pixel drivers EPD, a scan initialization line GIL that transmits a scan initialization signal GI (see FIG. 5) to the light-emitting pixel drivers EPD, a data line DL that transmits a data signal Vdata (see FIG. 5) to the light-emitting pixel drivers EPD, an initialization voltage line VIL that transmits an initialization voltage VINT (see FIG. 5) to the light-emitting pixel drivers EPD, a first power line VDL that transmits a first power source ELVDD (see FIG. 5) to the light-emitting pixel drivers EPD, and a second power line VSL that transmits a second power source ELVSS (see FIG. 5) to the light-emitting elements LE (see FIG. 5).

The circuit layer 120 may further include a first power additional line VDAL to reduce the resistance of the first power line VDL, and a second power additional line VSAL to reduce the resistance of the second power line VSL.

The first power additional line VDAL may extend in a direction crossing the first power line VDL, and may be electrically connected to the first power line VDL.

The second power additional line VSAL may extend in a direction crossing the second power line VSL, and may be electrically connected to the second power line VSL.

The data lines DL may include a first data line DL1 that transmits the data signal Vdata (see FIG. 5) of the first light-emitting pixel driver EPD1, a second data line DL2 that transmits the data signal Vdata (see FIG. 5) of the second light-emitting pixel driver EPD2, and a third data line DL3 that transmits the data signal Vdata (see FIG. 5) of the third light-emitting pixel driver EPD3.

Referring to FIG. 5, the light-emitting pixel driver EPD may be electrically connected between the first power source ELVDD and the light-emitting element LE, and the light-emitting element LE may be electrically connected between the light-emitting pixel driver EPD and the second power source ELVSS.

The light-emitting element LE may be an organic light-emitting diode (OLED) having an organic light-emitting layer, a quantum dot light-emitting diode (LED) including a quantum dot light-emitting layer, a micro LED, or an inorganic LED having an inorganic semiconductor.

The second power source ELVSS may be at a voltage level that is lower than that of the first power source ELVDD.

For example, the anode electrode of the light-emitting element LE may be electrically connected to the light-emitting pixel driver EPD, and the cathode electrode of the light-emitting element LE may be electrically connected to the second power source ELVSS.

The light-emitting pixel driver EPD may include a first transistor ST1 that generates a driving current of the light-emitting element LE, and one or more transistors ST2 and ST3 and one or more capacitors C1 electrically connected to the first transistor ST1.

The first transistor ST1 may be electrically connected between the first power line VDL and the light-emitting element LE. The first electrode of the first transistor ST1 may be electrically connected to the first power line VDL. The second electrode of the first transistor ST1 may be electrically connected to a second node N2 and the anode electrode of the light-emitting element LE. The first gate electrode of the first transistor ST1 may be electrically connected to the first node N1 and the second transistor ST2. The second gate electrode of the first transistor ST1 may be electrically connected to the second node N2.

The second transistor ST2 may be electrically connected between the data line DL and the first node N1. The gate electrode of the second transistor ST2 may be electrically connected to the scan write line GWL. For example, the second transistor ST2 may be turned on by the scan write signal of the scan write line GWL. When the second transistor ST2 is turned on, the data signal Vdata of the data line DL may be transmitted to the first node N1.

Due to the data signal Vdata transmitted to the first node N1, the voltage difference between the gate electrode of the first transistor ST1 and the first electrode of the first transistor ST1, that is, the gate-source voltage difference, may be the difference voltage between the first power source ELVDD and the data signal Vdata and thus may be greater than the threshold voltage of the first transistor ST1.

Accordingly, when the first transistor ST1 is turned on, a source-drain current of a magnitude corresponding to the data signal Vdata may be generated between the first electrode and the second electrode of the first transistor ST1. In addition, the source-drain current of the first transistor ST1 may be supplied as a driving current to the light-emitting element LE.

Accordingly, because a driving current of a magnitude corresponding to the data signal Vdata is supplied to the light-emitting element LE, the light-emitting element LE may emit light with luminance corresponding to the data signal Vdata.

The first capacitor C1 may be electrically connected between the first node N1 and the second node N2. The first capacitor C1 may be charged by the data signal Vdata transmitted to the first node N1 through the turned-on second transistor ST2. Accordingly, the potential of the first node N1 may be maintained for a period of time (e.g., predetermined period of time) due to the voltage charged in the first capacitor C1.

The third transistor ST3 may be electrically connected between the initialization voltage line VIL and the second node N2. The gate electrode of the third transistor ST3 may be electrically connected to the scan initialization line GIL. For example, the third transistor ST3 may be turned on by the scan initialization signal GI of the scan initialization line GIL. When the third transistor ST3 is turned on, the potential of the second node N2, that is, the potential of the anode electrode of the light-emitting element LE, may be initialized to the initialization voltage VINT of the initialization voltage line VIL.

As illustrated in FIG. 5, according to one embodiment, each of the first, second, and third transistors ST1, ST2, and ST3 may be an N-type MOSFET. However, this is merely an example, and at least one of the first, second, or third transistors ST1, ST2, or ST3 may be a P-type MOSFET.

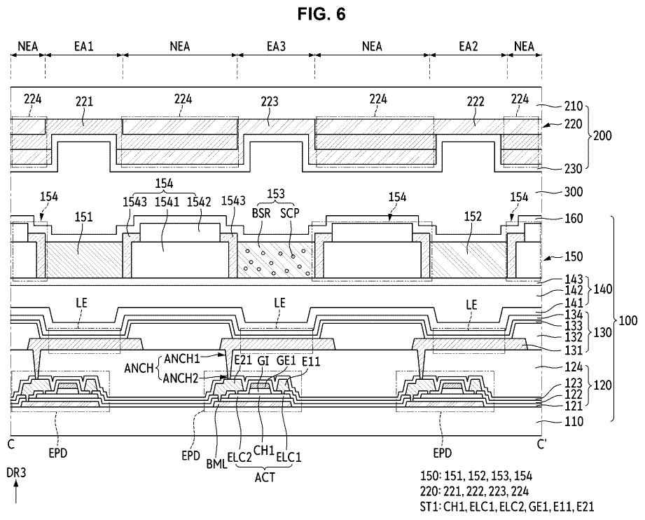

FIG. 6 is a cross-sectional view taken along the line C-C′ of FIG. 3.

Referring to FIG. 6, the first substrate 100 of the display device 10 according to embodiments may include the first support substrate 110, the circuit layer 120 located on the first support substrate 110, a planarization layer 124 located on the circuit layer 120, the element layer 130 located on the planarization layer 124, the encapsulation layer 140 located on the element layer 130, the color conversion layer 150 located on the encapsulation layer 140, and a color conversion capping layer 160 covering the color conversion layer 150.

The circuit layer 120 may include a buffer layer 121 located on the first support substrate 110, a first interlayer insulating layer 122 located on the buffer layer 121, and a second interlayer insulating layer 123 located on the first interlayer insulating layer 122.

Each of the buffer layer 121, the first interlayer insulating layer 122, and the second interlayer insulating layer 123 may include an inorganic insulating material.

The circuit layer 120 may include the light-emitting pixel drivers EPD that transmit a driving current to the light-emitting elements LE, and the lines VDL, DL, VIL, GWL, and GIL (see FIG. 5).

Each of the light-emitting pixel drivers EPD may include two or more transistors ST1, ST2, and ST3 (see FIG. 5).

The first transistor ST1 of each of the light-emitting pixel drivers EPD may include an active layer ACT located on the buffer layer 121, a gate electrode GE1 located on a gate-insulating layer GI covering a channel portion CH1 of the active layer ACT, and a first electrode E11 and a second electrode E21 located on the first interlayer insulating layer 122 covering the active layer ACT and the gate electrode GE1.

The active layer ACT may overlap a light-blocking layer BML on the first support substrate 110.

The buffer layer 121 may cover the light-blocking layer BML.

The active layer ACT may include the channel portion CH1, a first electrode portion ELC1 connected to one side of the channel portion CH1, and a second electrode portion ELC2 connected to the other side of the channel portion CH1.

The gate-insulating layer GI may include an inorganic insulating material.

The first electrode E11 may be electrically connected to the first electrode portion ELC1 of the active layer ACT through a hole penetrating the first interlayer insulating layer 122.

The second electrode E21 may be electrically connected to the second electrode portion ELC2 of the active layer ACT through a hole penetrating the first interlayer insulating layer 122.

The second interlayer insulating layer 123 may cover the first interlayer insulating layer 122, the first electrode E11, and the second electrode E21.

The planarization layer 124 may be located on the second interlayer insulating layer 123.

The element layer 130 includes the light-emitting elements LE located in the emission areas EA. The light-emitting elements LE may emit light in the fourth wavelength band.

Each of the light-emitting elements LE may have a structure in which a light-emitting layer 133 is located between an anode electrode 131 and a cathode electrode 134 opposing each other.

For example, the element layer 130 may include the anode electrodes 131 located in the emission areas EA, a pixel-defining layer 132 located in the non-emission area NEA and covering the edges of the anode electrodes 131, the light-emitting layer 133 located on the anode electrodes 131 and the pixel-defining layer 132, and the cathode electrode 134 located on the light-emitting layer 133.

As another example, the light-emitting layer 133 may be located in each of the emission areas EA.

The anode electrodes 131 may be electrically connected to the light-emitting pixel drivers EPD through an anode connection hole ANCH. For example, the anode electrode 131 may be electrically connected to the second electrode E21 of the first transistor ST1 of the light-emitting pixel driver EPD through the anode connection hole ANCH.

The anode connection hole ANCH may include a first anode connection hole ANCH1 penetrating the planarization layer 124, and a second anode connection hole ANCH2 penetrating the second interlayer insulating layer 123.

The encapsulation layer 140 may include a first encapsulation layer 141 located on the element layer 130 and containing an inorganic insulating material, a second encapsulation layer 142 located on the first encapsulation layer 141 and containing an organic insulating material, and a third encapsulation layer 143 located on the second encapsulation layer 142 and containing an inorganic insulating material.

The color conversion layer 150 may include a first color conversion portion 151 located in the first emission area EA1, a second color conversion portion 152 located in the second emission area EA2, a light-transmitting portion 153 located in the third emission area EA3, and a partition wall 154 located among the first color conversion portion 151, the second color conversion portion 152, and the light-transmitting portion 153.

The first color conversion portion 151 may convert light in the fourth wavelength band emitted from the light-emitting element LE of the first emission area EA1 into light in the first wavelength band. The first color conversion portion 151 may be a cured product of a first ink material including a base resin, and first color conversion particles dispersed in the base resin. The first color conversion particle may convert light in the fourth wavelength band into light in the first wavelength band.

The second color conversion portion 152 may convert light in the fourth wavelength band emitted from the light-emitting element LE of the second emission area EA2 into light in the second wavelength band. The second color conversion portion 152 may be a cured product of a second ink material including a base resin, and second color conversion particles dispersed in the base resin. The second color conversion particle may convert light in the fourth wavelength band into light in the second wavelength band.

The light-transmitting portion 153 may transmit and scatter light in the fourth wavelength band emitted from the light-emitting element LE of the third emission area EA3. The light-transmitting portion 153 may include a base resin BSR and scattering particles SCP dispersed in the base resin BSR.

The scattering particles SCP may be metal oxide particles or organic particles. The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂). The organic particles may be acrylic resin or urethane resin.

Each of the first color conversion portion 151 and the second color conversion portion 152 may further include scattering particles dispersed in the base resin.

Each of the first color conversion particle and the second color conversion particle may be at least one of a quantum dot, a quantum rod, or a phosphor.

The quantum dot may be any one selected from Group IV nanocrystals, Group II-VI compound nanocrystals, Group III-V compound nanocrystals, Group IV-VI nanocrystals, and combinations thereof.

The first color conversion portion 151, the second color conversion portion 152, and the light-transmitting portion 153 may include the same base resin, or may include different base resins.

The partition wall 154 may surround the vicinity of each of the first color conversion portion 151, the second color conversion portion 152, and the light-transmitting portion 153. The partition wall 154 may include a first partition wall 1541 located among the first color conversion portion 151, the second color conversion portion 152, and the light-transmitting portion 153, a reflective wall 1543 that covers the side surface of the first partition wall 1541 and reflects light, and a second partition wall 1542 located on the first partition wall 1541 and having a hydrophobic property.

The first partition wall 1541 may designate a boundary among the first color conversion portion 151, the second color conversion portion 152, and the light-transmitting portion 153. The first partition wall 1541 may include an organic material.

The reflective wall 1543 may include a reflective metal material. The reflective wall 1543 may reflect light heading toward the first partition wall 1541 to each of the first color conversion portion 151, the second color conversion portion 152, and the light-transmitting portion 153. The reflective wall 1543 may not cover a central portion of the top surface of the first partition wall 1541. In this way, the introduction or concentration of static electricity due to the conductivity of the reflective wall 1543 including a metal material may be reduced, so that the likelihood of damage due to static electricity may be reduced or prevented.

The second partition wall 1542 may include an organic material having a hydrophobic surface. Due to the hydrophobic property of the second partition wall 1542, the first ink material dropped into the first emission areas EA1 for disposition/deposition of the first color conversion portion 151 may be facilitated to be accommodated and agglomerated within the first emission area EA1 surrounded by the partition wall 154. Likewise, the second ink material dropped into the second emission areas EA2 for the disposition/deposition of the second color conversion portion 152 may be facilitated to be accommodated and agglomerated within the second emission area EA2 surrounded by the partition wall 154. For example, the second partition wall 1542 may contact the top surface of the first partition wall 1541, and may overlap a portion of the reflective wall 1543.

The color conversion capping layer 160 may cover the color conversion layer 150, and may include an inorganic insulating material.

According to embodiments, the second substrate 200 of the display device 10 may include the second support substrate 210, the color filter layer 220 located on one surface of the second support substrate 210, and a filter capping layer 230 covering the color filter layer 220.

In a direction in which light from the display device 10 is emitted (e.g., a third direction DR3), the color filter layer 220 may be located on the color conversion layer 150, and the second support substrate 210 may be located on the color filter layer 220. Accordingly, the light emitted from the light-emitting elements LE of the element layer 130 may pass through the color conversion layer 150, the color filter layer 220, and the second support substrate 210, and may be emitted to the outside.

The color filter layer 220 may include a first filter portion 221 that is located in the first emission area EA1 and that transmits light in the first wavelength band, a second filter portion 222 that is located in the second emission area EA2 and that transmits light in the second wavelength band, a third filter portion 223 that is located in the third emission area EA3 and transmits light in the third wavelength band, and a light-blocking portion 224 that is located in the non-emission area NEA and that blocks light.

Each of the first filter portion 221, the second filter portion 222, and the third filter portion 223 may include a colorant, such as a dye or pigment. The colorant may be a material that absorbs light in the remaining wavelength bands excluding a wavelength band (e.g., predetermined wavelength band).

For example, the first filter portion 221 may include a colorant that absorbs light in the remaining wavelength bands excluding the first wavelength band among the light transmitted through the color conversion layer 150, and thus may transmit light in the first wavelength band. The second filter portion 222 may include a colorant that absorbs light in the remaining wavelength bands excluding the second wavelength band among the light transmitted through the color conversion layer 150, and thus may transmit light in the second wavelength band. The third filter portion 223 may include a colorant that absorbs light in the remaining wavelength bands excluding the third wavelength band among the light transmitted through the color conversion layer 150, and thus may transmit light in the third wavelength band.

The light-blocking portion 224 may have a structure in which two or more filter portions among the first filter portion 221, the second filter portion 222, and the third filter portion 223 are stacked. Alternatively, the light-blocking portion 224 may include a material that absorbs light, such as a black matrix material.

In one or more embodiments, a light reproduction member located in a first margin area and a second margin area may overlap the light-blocking portion 224 of the non-emission area NEA. Accordingly, color mixing or light leakage caused by the light reproduction member may be reduced.

The filter capping layer 230 may cover the color filter layer 220, and may include an inorganic insulating material.

The display device 10 may further include a low refractive index layer located between the color filter layer 220 and the color conversion layer 150. The low refractive index layer may include an organic material having a refractive index of about 1.1 or more and about 1.4 or less.

As an example, the low refractive index layer may be located on the color conversion capping layer 160, or may be located on the filter capping layer 230.

According to embodiments, the display device 10 may further include the filling layer 300 located between the first substrate 100 and the second substrate 200. The filling layer 300 may fill the separation space between the first substrate 100 and the second substrate 200. The filling layer 300 may be located between the color conversion capping layer 160 of the first substrate 100 and the filter capping layer 230 of the second substrate 200. The filling layer 300 may include an organic material that has light transmittance and a tackifying property. As an example, the filling layer 300 may include a Si-based organic material or an epoxy-based organic material.

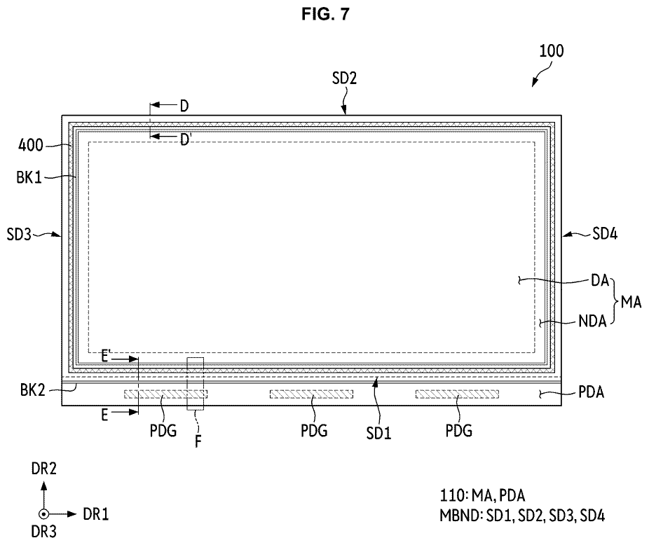

FIG. 7 is a plan view showing the first substrate of FIG. 2.

As illustrated in FIG. 7, the first substrate 100 of the display device 10 according to embodiments may include the first support substrate 110 including a main region MA and a pad area PDA.

The main region MA may include the display area DA in which the emission areas EA (see FIG. 3) are arranged, and the non-display area NDA surrounding the display area DA.

For example, when the main region MA has a quadrilateral shape, an edge MBND (SD1, SD2, SD3, and SD4) of the main region MA may include a first side SD1 and a second side SD2 extending in the first direction DR1, and a third side SD3 and a fourth side SD4 extending in the second direction DR2.

The pad area PDA may be connected to at least a portion of one side (e.g., the first side SD1) of the edge MBND of the main region MA.

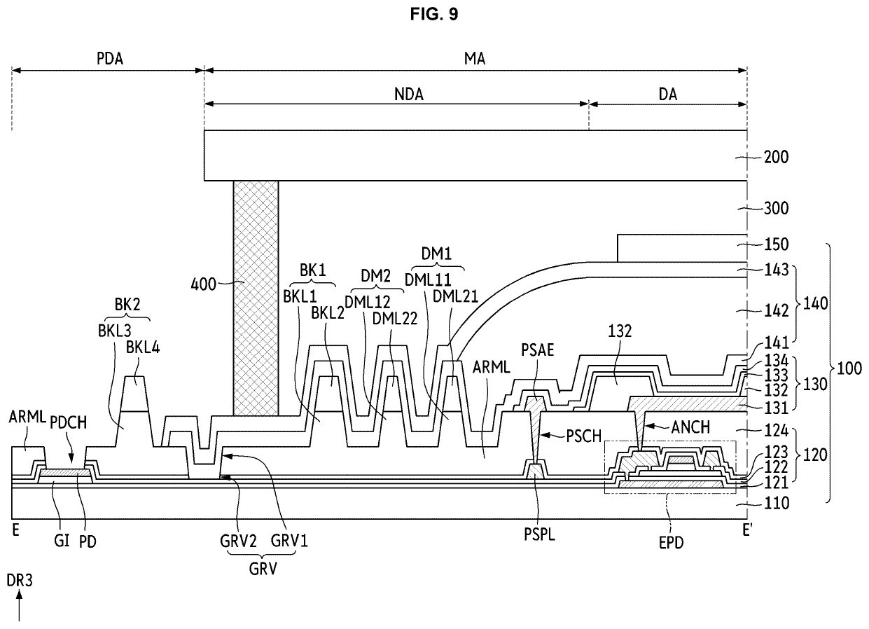

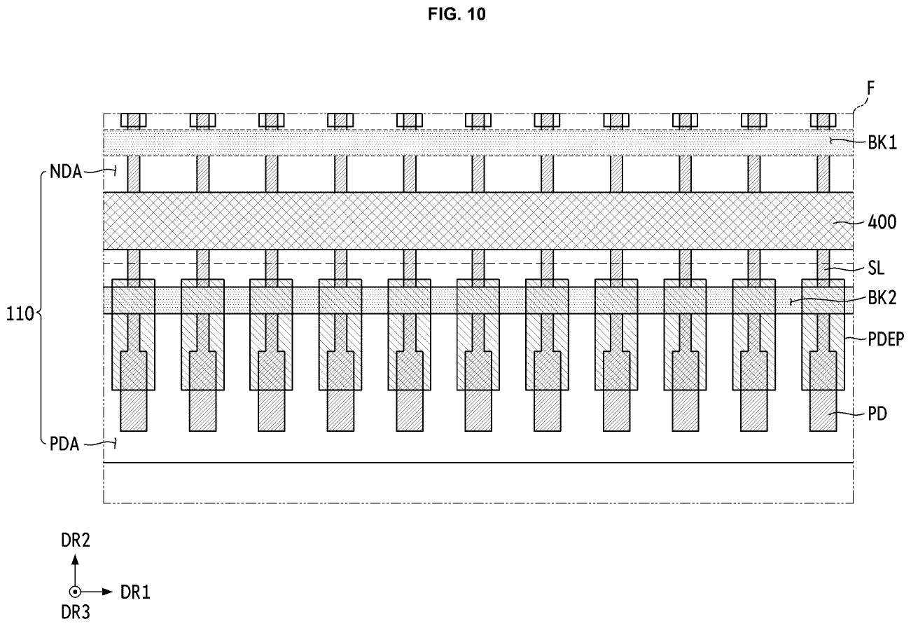

The circuit layer 120 (see FIG. 2) may include pads PD (see FIGS. 9 and 10) located in the pad area PDA.

The lines VDL, DL, VIL, GWL, and GIL (see FIG. 5) of the circuit layer 120 may extend to the non-display area NDA and the pad area PDA, and may be electrically connected to the pads PD, respectively.

A pad group PDG may be formed from two or more adjacent pads PD among the pads PD. At least one pad group PDG may be located in the pad area PDA.

The sealing layer 400 of the display device 10 according to embodiments may be located in the non-display area NDA.

According to embodiments, the first substrate 100 may further include a first bank BK1 located in the non-display area NDA, and a second bank BK2 located in the pad area PDA.

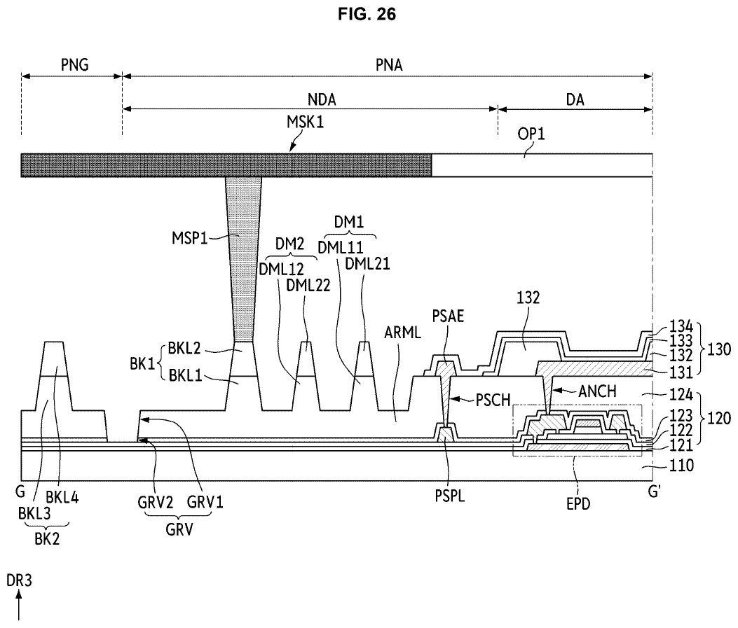

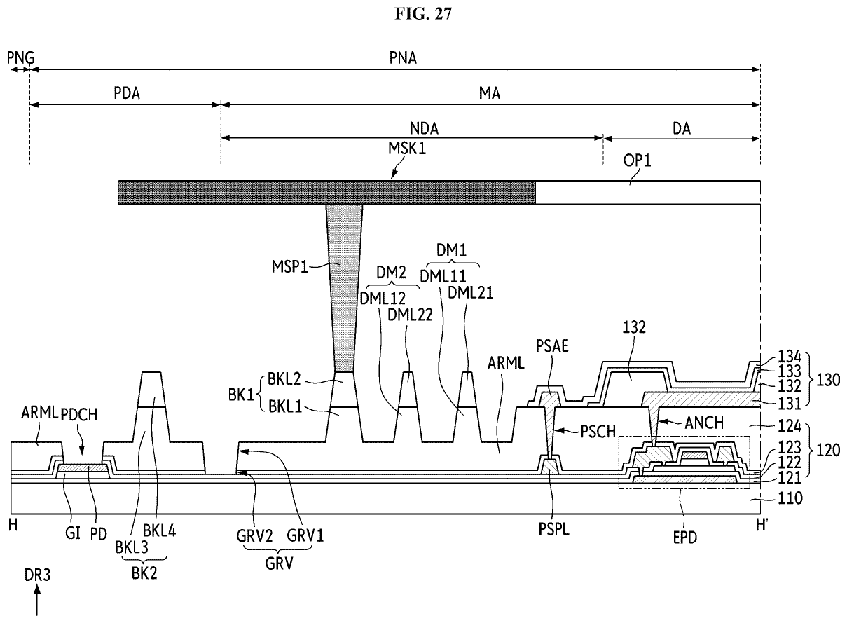

The first bank BK1 may be located between the edge of the display area DA and the sealing layer 400 in the non-display area NDA. The first bank BK1 may be used to hold a first mask MSK1 (see FIGS. 26 and 27) in the process of depositing (e.g., disposing) the cathode electrode 134 (see FIG. 6) of the element layer 130 (see FIG. 6). Alternatively, the first mask MSK1 may be used also in the process of depositing the light-emitting layer 133 of the element layer 130 (see FIG. 6).

The second bank BK2 may extend parallel to one side (e.g., the first side SD1) of the main region MA adjacent to the pad area PDA. For example, the second bank BK2 located in the pad area PDA may extend in the first direction DR1. The second bank BK2 may be located between the pads PD and one side SD1 of the main region MA.

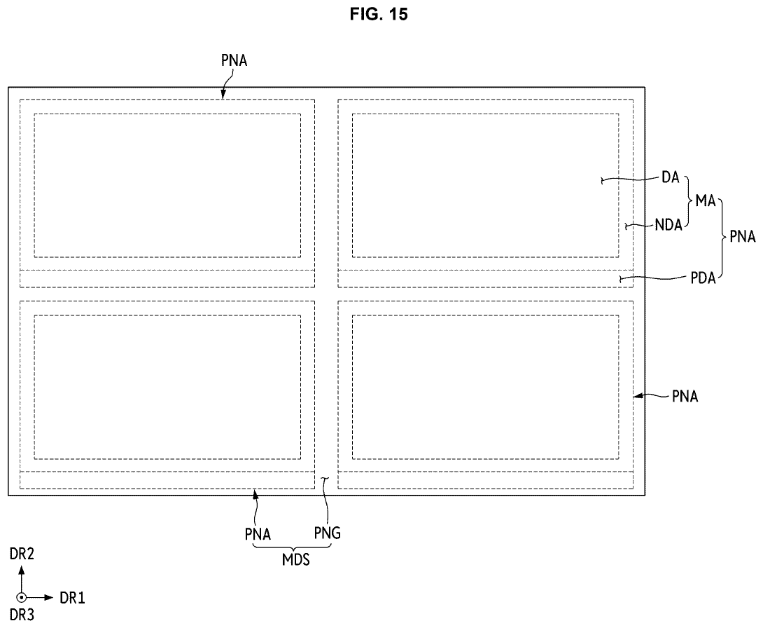

Before the process of individually separating the first substrates 100 from a mother substrate MDS (see FIG. 15) by scribing along the edge of each of panel areas PNA (see FIG. 15), the second bank BK2 may be located in a closed curve shape that surrounds a portion of the periphery of the panel area PNA and that crosses the pad area PDA.

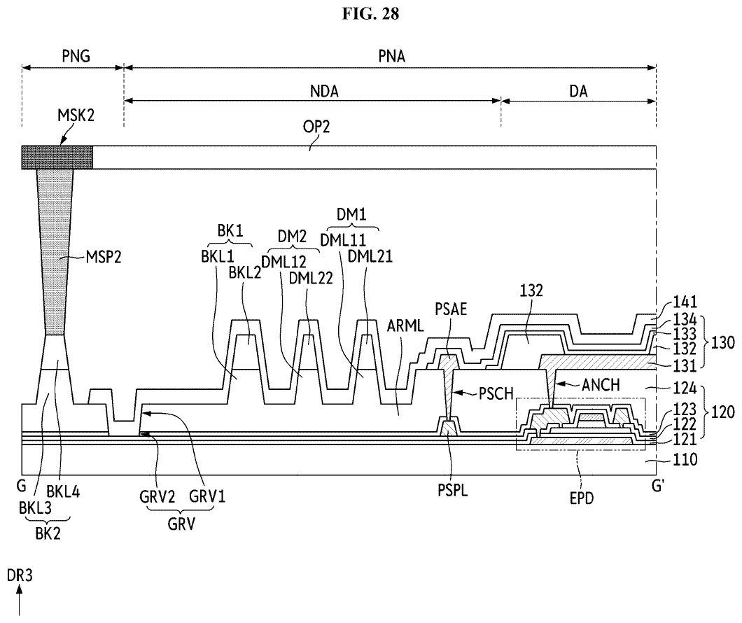

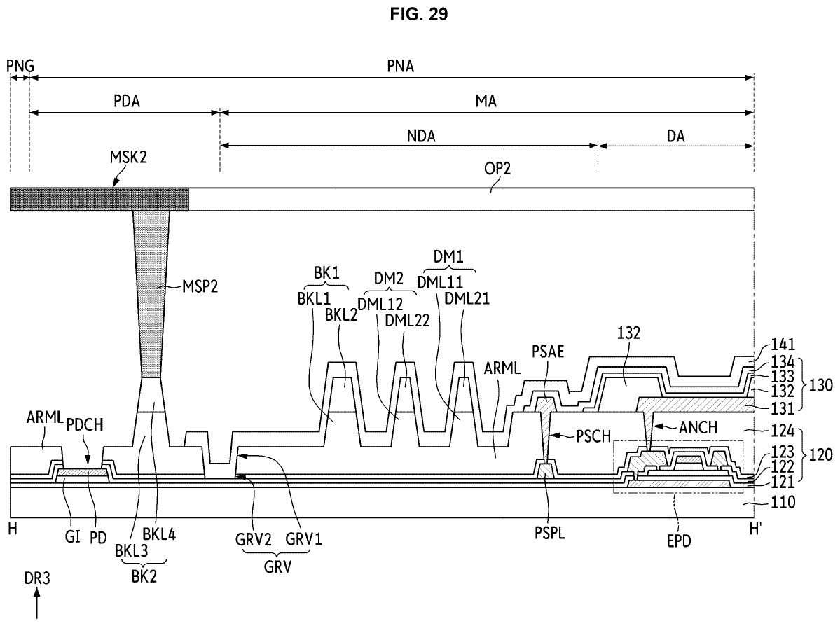

Accordingly, in the process of depositing the first encapsulation layer 141 (see FIG. 6) and the second encapsulation layer 142 (see FIG. 6) of the encapsulation layer 140 (see FIG. 6), the second bank BK2 may be used to mount a second mask MSK2 (see FIGS. 28 and 29).

In addition, after the process of individually separating the first substrates 100 by scribing, a portion of the second bank BK2 located in the pad area PDA may remain in the first substrate 100.

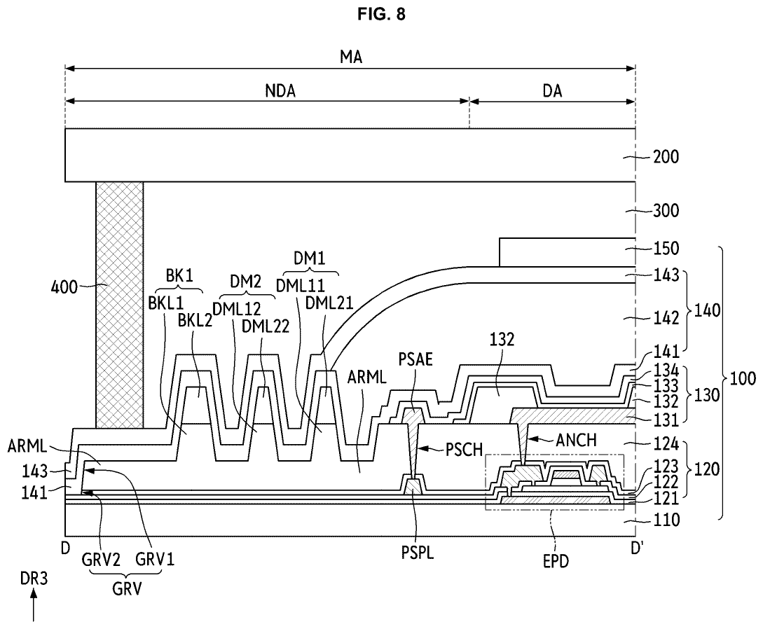

FIG. 8 is a cross-sectional view taken along the line D-D′ of FIG. 7. FIG. 9 is a cross-sectional view taken along the line E-E′ of FIG. 7.

Referring to FIGS. 8 and 9, the first substrate 100 of the display device 10 according to embodiments may further include an auxiliary residual layer ARML extending from the planarization layer 124, and deposited with a lesser thickness than the planarization layer 124, in the non-display area NDA and the pad area PDA.

For example, when the second interlayer insulating layer 123 in the non-display area NDA and the pad area PDA is exposed to an etching process in the process of forming the second anode connection hole ANCH2 and in the process of depositing the anode electrode 131, the conductive layer covered with the second interlayer insulating layer 123 may be damaged, so that disconnection defects or short-circuit defects may occur.

Accordingly, to reduce or prevent exposure of the second interlayer insulating layer 123 to the etching process in the process of forming the second anode connection hole ANCH2 and the process of depositing the anode electrode 131, the auxiliary residual layer ARML covering the second interlayer insulating layer 123 may be located in the non-display area NDA and the pad area PDA.

In addition, according to embodiments, even after the anode electrode 131 is placed, the auxiliary residual layer ARML may remain without being removed. In this way, the number of etching processes is reduced by omitting the removal process of the auxiliary residual layer ARML, so that it may be suitable or advantageous in streamlining the method for manufacturing the display device 10.

The first bank BK1 of the non-display area NDA and the second bank BK2 of the pad area PDA may be located on the auxiliary residual layer ARML. The first bank BK1 may include a first bank layer BKL1 located on the auxiliary residual layer ARML, and a second bank layer BKL2 located on the first bank layer BKL1.

The second bank BK2 may include a third bank layer BKL3 located on the auxiliary residual layer ARML, and a fourth bank layer BKL4 located on the third bank layer BKL3.

Each of the auxiliary residual layer ARML, the first bank layer BKL1, the second bank layer BKL2, the third bank layer BKL3, and the fourth bank layer BKL4 may include an organic insulating material.

For example, the auxiliary residual layer ARML, the first bank layer BKL1, and the third bank layer BKL3 may be located in/at the same layer as the planarization layer 124.

For example, the auxiliary residual layer ARML may be in the same layer as a portion of the planarization layer 124 adjacent to the circuit layer 120, and the first bank layer BKL1 and the third bank layer BKL3 may be in the same layer as another remaining portion of the planarization layer 124.

In addition, the second bank layer BKL2 and the fourth bank layer BKL4 may be located in/at the same layer as the pixel-defining layer 132.

The first substrate 100 of the display device 10 according to embodiments may further include one or more dam portions DM1 and DM2 located between the edge of the display area DA and the first bank BK1 in the non-display area NDA. One or more dam portions DM1 and DM2 may be located on the auxiliary residual layer ARML. One or more dam portions DM1 and DM2 may include two or more dam layers DML11 and DML21, and DML12 and DML22 stacked on each other, respectively.

Each of two or more dam layers DML11 and DML21, and DML12 and DML22 may include an organic insulating material. For example, two or more dam layers DML11 and DML21, and DML12 and DML22 may include first dam layers DML11 and DML12 located on the auxiliary residual layer ARML, and second dam layers DML21 and DML22 located on the first dam layers DML11 and DML12.

The auxiliary residual layer ARML and the first dam layers DML11 and DML12 may be located in the same layer as the planarization layer 124. For example, the auxiliary residual layer ARML may be in the same layer as a portion of the planarization layer 124 adjacent to the circuit layer 120, and the first dam layers DML11 and DML12 may be in the same layer as another remaining portion of the planarization layer 124.

The second dam layers DML21 and DML22 may be located in the same layer as the pixel-defining layer 132.

The circuit layer 120 may further include a power supply line PSPL located in the non-display area NDA for transmitting the second power source ELVSS (see FIG. 5). The power supply line PSPL may be located on the first interlayer insulating layer 122.

The cathode electrode 134 may be electrically connected to the power supply line PSPL through a power supply auxiliary electrode PSAE.

For example, the pixel-defining layer 132 may be located in the display area DA, and the cathode electrode 134 may extend to the non-display area NDA, and may contact the power supply auxiliary electrode PSAE.

The power supply auxiliary electrode PSAE may be located on the planarization layer 124, and may be electrically connected to the power supply line PSPL through a power supply connection hole PSCH.

The encapsulation layer 140 may include the first encapsulation layer 141, the second encapsulation layer 142, and the third encapsulation layer 143.

According to embodiments, the first encapsulation layer 141 and the third encapsulation layer 143 may extend to the edge MBND of the main region MA, and the side surfaces of the first encapsulation layer 141 and the third encapsulation layer 143 may be parallel to the side surface of the first support substrate 110 at the second side SD2, the third side SD3, and the fourth side SD4 that are not in contact with the pad area PDA in the edge MBND of the main region MA.

In addition, the first encapsulation layer 141 and the third encapsulation layer 143 may extend from one side SD1 of the main region MA to the pad area PDA, and may be adjacent to the second bank BK2.

Accordingly, the first encapsulation layer 141 may cover not only the element layer 130 in the display area DA, but also one or more dam portions DM1 and DM2 and the first bank BK1 located in the non-display area NDA. In addition, the first encapsulation layer 141 may cover the auxiliary residual layer ARML of the non-display area NDA and the pad area PDA.

The second encapsulation layer 142 may be located in an area surrounded by one or more dam portions DM1 and DM2.

The third encapsulation layer 143 may contact the first encapsulation layer 141 in a portion between the edge MBND of the main region MA and one or more dam portions DM1 and DM2 in the non-display area NDA. In addition, the third encapsulation layer 143 may contact the first encapsulation layer 141 in a portion between one side SD1 of the main region MA and the second bank BK2 in the pad area PDA. In this way, the first encapsulation layer 141 and the third encapsulation layer 143 including an inorganic insulating material may extend to the edge MBND of the main region MA, so that the sealing layer 400 of the non-display area NDA may be located on the third encapsulation layer 143.

The first substrate 100 of the display device 10 according to embodiments may further include a groove GRV that extends along the edge MBND of the main region MA and that penetrates the auxiliary residual layer ARML.

The groove GRV may include a first groove GRV1 penetrating the auxiliary residual layer ARML. In one or more embodiments, the groove GRV may further include a second groove GRV2 that is continuous with the first groove GRV1, and that penetrates the second interlayer insulating layer 123.

Accordingly, the first encapsulation layer 141 may contact the second interlayer insulating layer 123 or the first interlayer insulating layer 122 through the groove GRV.

For example, the auxiliary residual layer ARML of the non-display area NDA connected to the planarization layer 124 of the display area DA may be sealed by inorganic bonding between the second interlayer insulating layer 123 or the first interlayer insulating layer 122 and the first encapsulation layer 141. Accordingly, permeation of oxygen or moisture by the auxiliary residual layer ARML may be reduced.

As illustrated in FIG. 9, the pad PD of the pad area PDA may be located on the gate-insulating layer GI.

The circuit board 13 (see FIG. 1) may be electrically connected to the pad PD through a pad connection hole PDCH. The pad connection hole PDCH may penetrate the auxiliary residual layer ARML, the second interlayer insulating layer 123, and the first interlayer insulating layer 122.

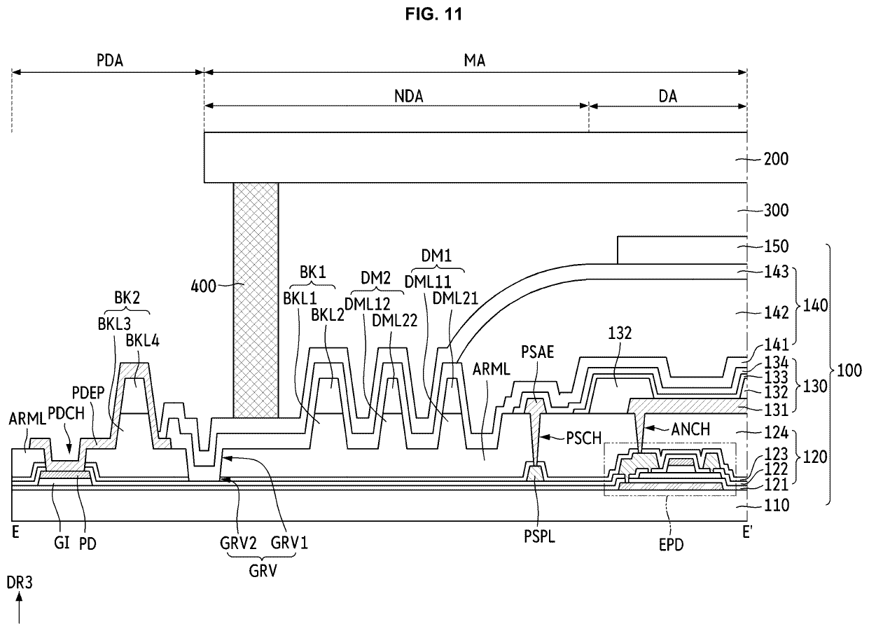

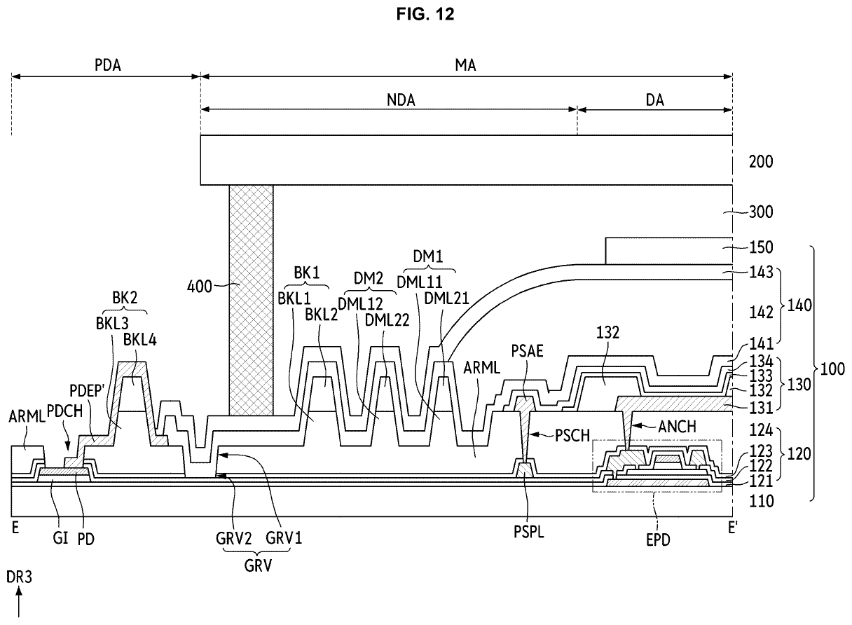

FIG. 10 is an enlarged view showing part F of FIG. 7 according to other embodiments. FIGS. 11 and 12 are cross-sectional views taken along the line E-E′ of

FIG. 7 according to the embodiments of FIG. 10.

Referring to FIG. 10, in the display device 10 according to other embodiments is substantially the same as the display device 10 of the embodiments illustrated in FIGS. 1 to 9, except that the first substrate 100 further includes pad extension portions PDEP that overlap the second bank BK2, and that contact the pads PD, respectively, so that redundant description will be omitted below.

The pads PD may be electrically connected to lines SL, respectively.

According to embodiments, each of the lines SL may transmit one of the first power source ELVDD (see FIG. 5), the second power source ELVSS (see FIG. 5), the data signal Vdata (see FIG. 5), the initialization voltage VINT (see FIG. 5), the scan write signal GW (see FIG. 5), and the scan initialization signal GI (see FIG. 5). At least some of the lines SL may intersect or cross the second bank BK2, the sealing layer 400, and the first bank BK1.

The pads PD may be electrically connected to the light-emitting pixel drivers EPD through the lines SL.

One of the pad extension portions PDEP may contact at least a portion of one of the pads PD.

For example, as illustrated in FIG. 11, according to one example, the pad extension portion PDEP may overlap the pad connection hole PDCH. Accordingly, the pad PD may be entirely in contact with the pad extension portion PDEP.

In this way, although the circuit board 13 is spaced apart from the pad PD due to interference from the second bank BK2, the circuit board 13 may be electrically connected to the pad PD through the pad extension portion PDEP.

Accordingly, regardless of the disposition/deposition of the second bank BK2, electrical connection between the pad PD and the circuit board 13 (see FIG. 1) may be implemented relatively easily through the pad extension portion PDEP.

Alternatively, as illustrated in FIG. 12, according to another example, the pad extension portion PDEP may be spaced apart from the edge of the first support substrate 110, and may contact only a portion of the pad PD.

In this way, the separation distance between the pad extension portion PDEP and the first support substrate 110 increases, so that the process margin for reducing or preventing the likelihood of the pad extension portion PDEP contacting the edge of the first support substrate 110 may increase. Accordingly, in the process of separating the first substrates 100, the pad extension portion PDEP may overlap the scribing line, so that the possibility of a process defect occurring may decrease.

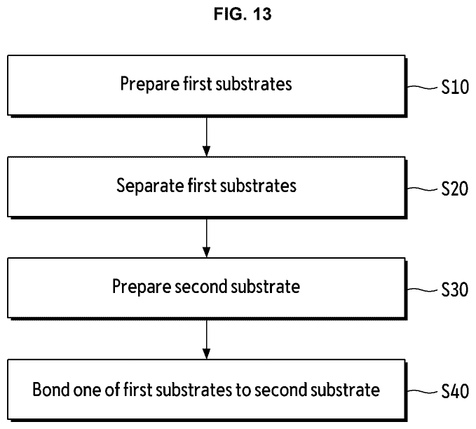

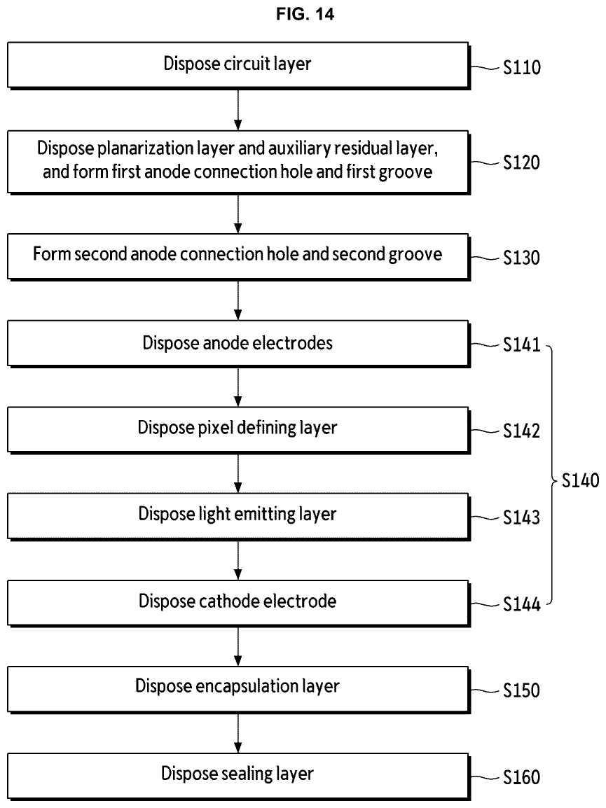

FIG. 13 is a flowchart illustrating a method for manufacturing the display device according to embodiments. FIG. 14 is a flowchart illustrating an operation of preparing a plurality of first substrates of FIG. 13. FIGS. 15, 16, 17, 18, 19, 20, 21, 22, 23, 24, 25, 26, 27, 28, 29, 30, 31, 32, 33, 34, 35, 36, 37, and 38 are process diagrams illustrating some of the operations in FIGS. 13 and 14.

Referring to FIG. 13, the method for manufacturing the display device 10 according to embodiments may include preparing a plurality of the first substrates 100 by using the mother substrate MDS (see FIG. 15) including a plurality of panel areas PNA (see FIG. 15) spaced apart from each other (operation S10), separating the plurality of first substrates 100 (operation S20), preparing the second substrate 200 (operation S30), and bonding one of the plurality of first substrates 100 to the second substrate 200 (operation S40).

As illustrated in FIG. 15, each of the plurality of panel areas PNA may include the main region MA, and the pad area PDA connected to at least a portion of one side of the main region MA.

As previously described with reference to FIGS. 1 and 3, the main region MA may include the display area DA including the emission areas EA arranged side by side, and the non-display area NDA located around the display area DA.

As illustrated in FIG. 14, the operation S10 of preparing a plurality of first substrates 100 may include depositing the circuit layer 120 in each of the plurality of panel areas PNA (operation S110), depositing the planarization layer 124 in the display area DA of each of the plurality of panel areas PNA by partially removing an organic insulating material covering the circuit layer 120, and depositing the auxiliary residual layer ARML having a thickness that is less than that of the planarization layer 124 in the non-display area NDA and the pad area PDA of each of the plurality of panel areas PNA (operation S120), depositing the element layer 130 on the planarization layer 124 (operation S140), depositing the encapsulation layer 140 on the element layer 130 and the auxiliary residual layer ARML (operation S150), and depositing the sealing layer 400 in the non-display area NDA of each of the plurality of panel areas PNA (operation S160).

The operation S140 of depositing the element layer 130 may include depositing the anode electrodes 131 in the emission areas EA (operation S141), depositing the pixel-defining layer 132 covering the edges of the anode electrodes 131 in the non-emission area NEA between the emission areas EA by partially removing an organic insulating material covering the anode electrodes 131 (operation S142), depositing the light-emitting layer 133 on the anode electrodes 131 and the pixel-defining layer 132 (operation S143), and depositing the cathode electrode 134 on the light-emitting layer 133 (operation S144).

In the operation S120 of depositing the planarization layer 124 and the auxiliary residual layer ARML, the first anode connection hole ANCH1 and the first groove GRV1 may be formed.

In addition, the operation S10 of preparing the plurality of first substrates 100 may further include forming the second anode connection hole ANCH2 and the second groove GRV2 before depositing the anode electrodes 131 (operation S130).

As illustrated in FIG. 15, in the operation S10 of preparing the plurality of first substrates 100, the mother substrate MDS may include the plurality of panel areas PNA spaced apart from each other, and a separation area PNG between the plurality of panel areas PNA.

In the operation S20 of separating the plurality of first substrates 100, the plurality of first substrates 100 may include the first support substrates 110 constituted with, or comprising, portions of the mother substrate MDS located in the plurality of panel areas PNA.

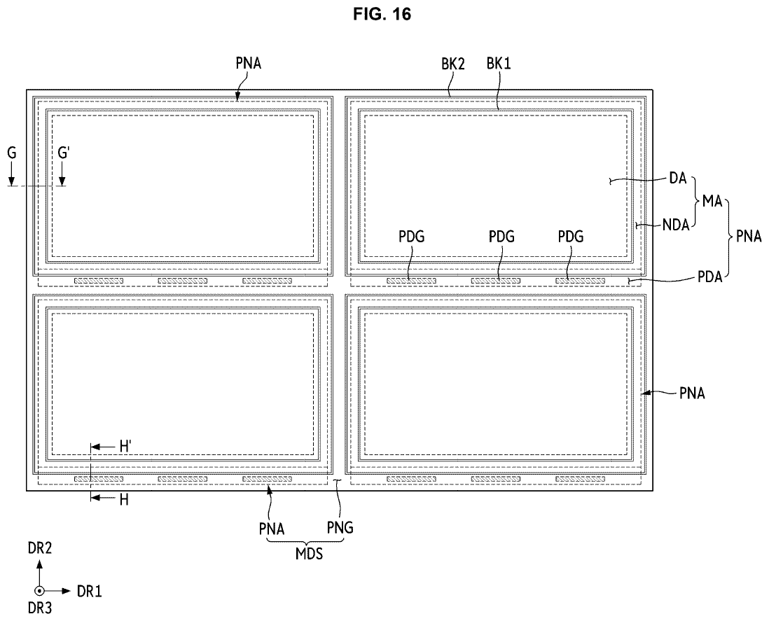

As illustrated in FIG. 16, after depositing the circuit layer 120, one or more pad groups including two or more pads PD adjacent to each other may be located in the pad area PDA of each of the plurality of panel areas PNA.

As illustrated in FIG. 16, after the operation S140 of depositing the element layer 130, the first bank BK1 may be located in the non-display area NDA of each of the plurality of panel areas PNA, and the second bank BK2 may be located in the pad area PDA and the separation area PNG of each of the plurality of the panel areas PNA.

The first bank BK1 may have a closed curve shape surrounding the edge of the display area DA of each of the plurality of panel areas PNA.

The second bank BK2 may have a closed curve shape that crosses the pad area PDA of each of the plurality of panel areas PNA, and surrounds the periphery of each of the plurality of panel areas PNA.

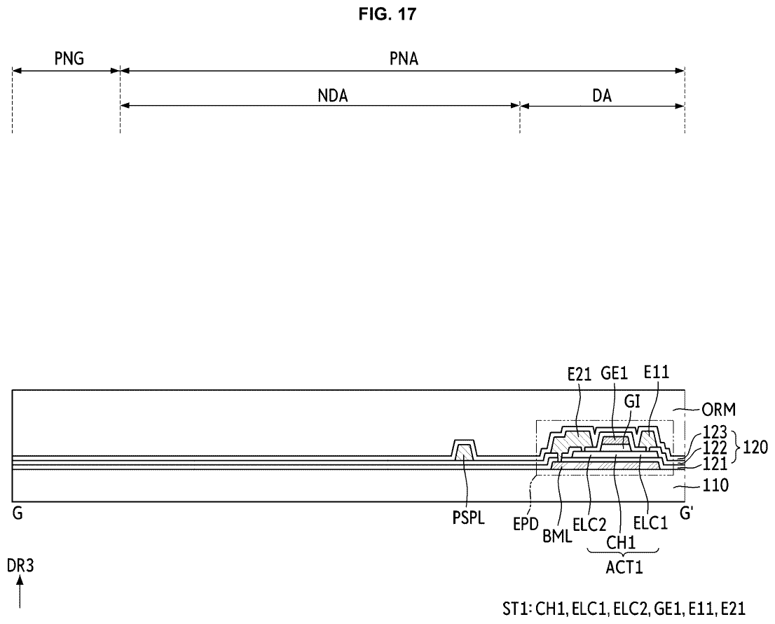

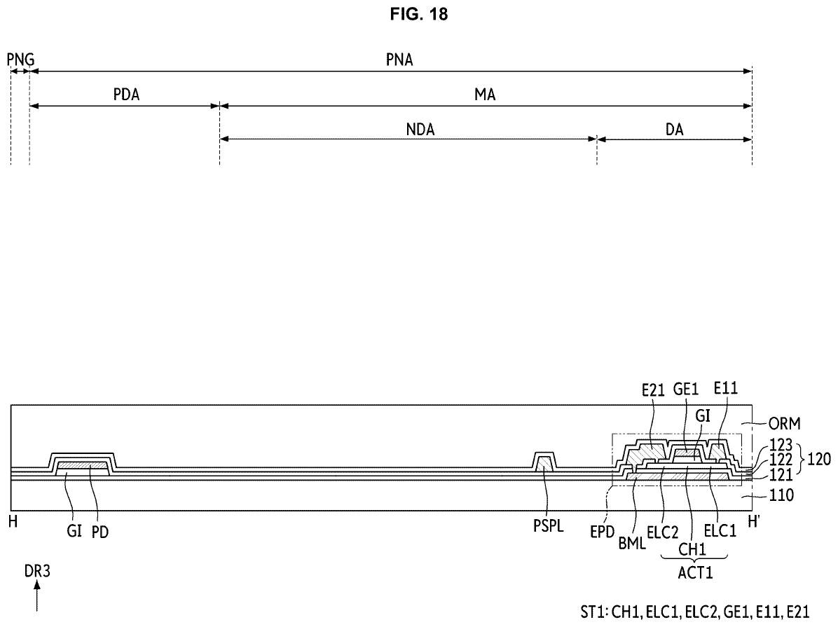

As illustrated in FIGS. 17 and 18, after the operation S110 of depositing the circuit layer 120, the circuit layer 120 may include the buffer layer 121 located on the first support substrate 110, the first interlayer insulating layer 122 located on the buffer layer 121, and the second interlayer insulating layer 123 located on the first interlayer insulating layer 122.

The circuit layer 120 may include the light-emitting pixel drivers EPD and the lines SL (see FIG. 10) that are electrically connected to the light-emitting pixel drivers EPD and that extend to the non-display area NDA and the pad area PDA, and the pads PD arranged in the pad area PDA and electrically connected to the lines SL.

The circuit layer 120 may further include the power supply line PSPL located in the non-display area NDA for transmitting the second power source ELVSS.

Each of the light-emitting pixel drivers EPD may include the first transistor ST1. The first transistor ST1 may include the active layer ACT located on the buffer layer 121, the gate electrode GE1 located on the gate-insulating layer GI covering the channel portion CH1 of the active layer ACT, and the first electrode E11 and the second electrode E21 located on the first interlayer insulating layer 122 covering the active layer ACT and the gate electrode GE1.

The active layer ACT may overlap the light-blocking layer BML on the first support substrate 110.

The buffer layer 121 may cover the light-blocking layer BML.

The second interlayer insulating layer 123 may cover the first interlayer insulating layer 122, the first electrode E11, and the second electrode E21.

The pads PD may be covered with the first interlayer insulating layer 122 and the second interlayer insulating layer 123.

The operation S120 of depositing the planarization layer 124 and the auxiliary residual layer ARML may include stacking an organic insulating material ORM on the second interlayer insulating layer 123.

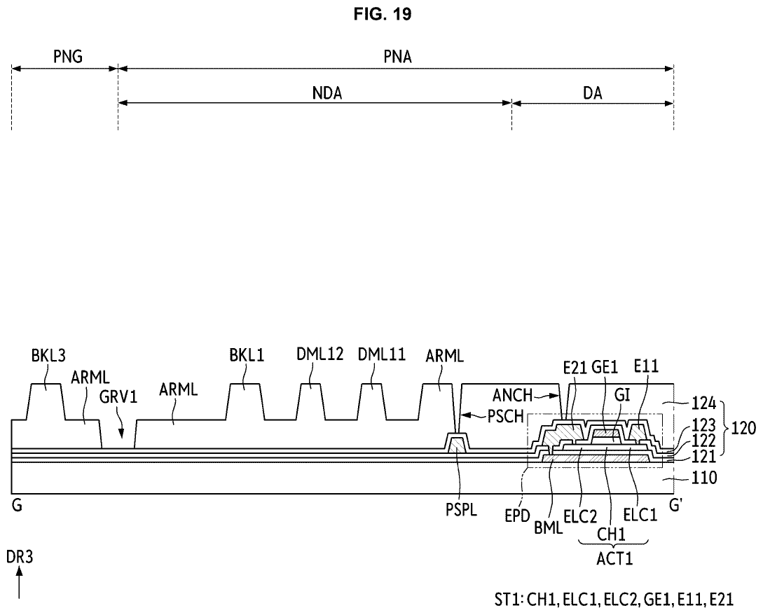

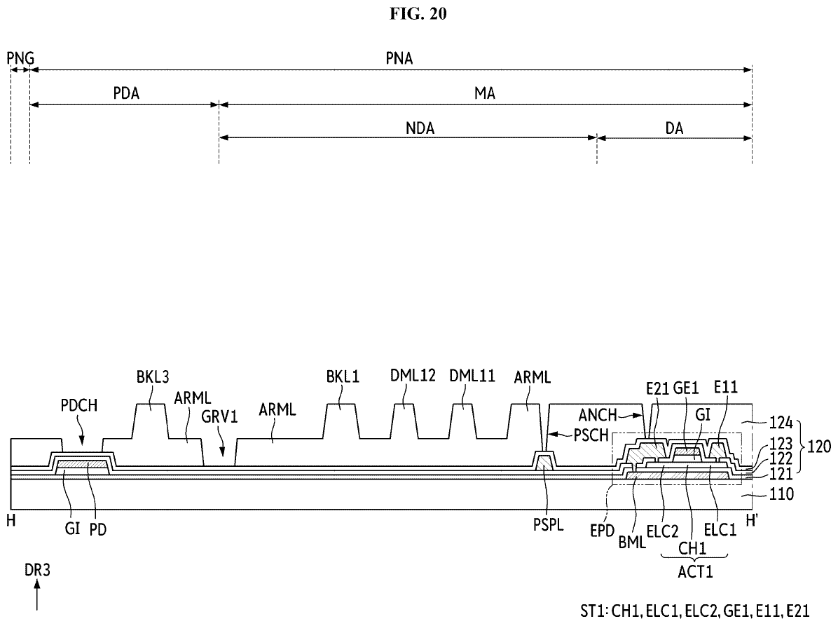

Referring to FIGS. 19 and 20, the operation S120 of depositing the planarization layer 124 and the auxiliary residual layer ARML may include a process of partially removing the organic insulating material ORM on the second interlayer insulating layer 123 by using a halftone mask.

Accordingly, the planarization layer 124 may be located in the display area DA by the unetched organic insulating material ORM, and the auxiliary residual layer ARML, which has a thickness that is less than that of the planarization layer 124, may be located in the non-display area NDA and the pad area PDA by the remainder of the organic insulating material ORM after being partially etched.

In addition, one or more first dam layers DML11 and DML12 and the first bank layer BKL1 may be located in the non-display area NDA by the unetched organic insulating material ORM, and the third bank layer BKL3 may be located in the pad area PDA and a gap area PNG.

One or more first dam layers DML11 and DML12 have a closed curve shape surrounding the edge of the display area DA (e.g., in plan view) and may be arranged sequentially.

The first bank layer BKL1 may have a closed curve shape surrounding one or more first dam layers DML11 and DML12 (e.g., in plan view).

The third bank layer BKL3 may have a closed curve shape surrounding the edge of the main region MA (e.g., in plan view). For example, a portion of the third bank layer BKL3 may surround the remaining sides, excluding one side that contacts the pad area PDA, among the edges of the main region MA in the gap area PNG, and another remaining portion of the third bank layer BKL3 may be located in the pad area PDA and surround one side of the main region MA.

In addition, the organic insulating material ORM may be completely removed, and the first anode connection hole ANCH1, a first power supply connection hole PSCH1, the first groove GRV1, and the first pad connection hole PDCH1 may be formed.

The first anode connection hole ANCH1 may face the second electrode E21 of the first transistor ST1.

The first power supply connection hole PSCH1 may face the power supply line PSPL.

The first groove GRV1 may extend along the edge MBND of the main region MA.

Accordingly, a portion of the first groove GRV1 may be located in the pad area PDA, and may be parallel to one side of the main region MA. In addition, another remaining portion of the first groove GRV1 may be parallel to the remaining sides, excluding one side that contacts the pad area PDA, among the edges of the main region MA.

The first pad connection hole PDCH1 may face each of the pads PD.

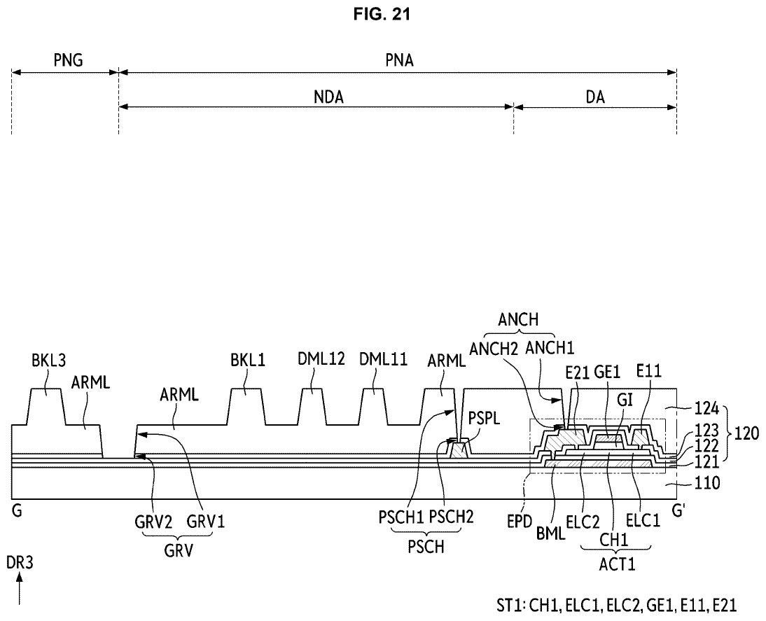

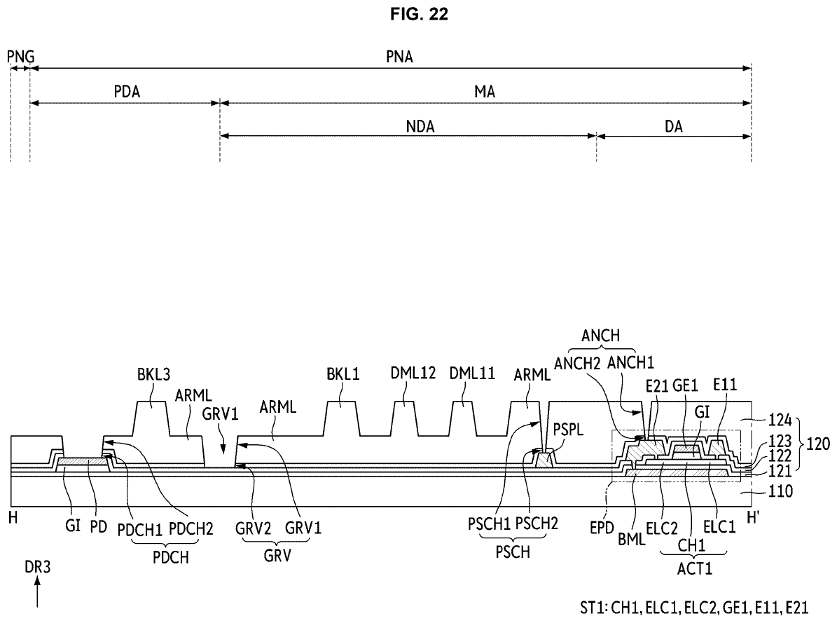

As illustrated in FIGS. 21 and 22, in the operation S130 of forming the second anode connection hole ANCH2 and the second groove GRV2, an etching process is performed on the inorganic material to partially remove the second interlayer insulating layer 123 and the first interlayer insulating layer 122, so that the second anode connection hole ANCH2 and the second groove GRV2 may be formed.

The second anode connection hole ANCH2 may be continuous with the first anode connection hole ANCH1, and may penetrate the second interlayer insulating layer 123. Accordingly, the anode connection hole ANCH including the first anode connection hole ANCH1 and the second anode connection hole ANCH2 may be prepared.

The second groove GRV2 may be continuous with the first groove GRV1, and may penetrate the second interlayer insulating layer 123. Accordingly, the groove GRV including the first groove GRV1 and the second groove GRV2 may be prepared.

In addition, in the operation S130 of forming the second anode connection hole ANCH2 and the second groove GRV2, a second power supply connection hole PSCH2 and a second pad connection hole PDCH2 may be formed.

The second power supply connection hole PSCH2 may be continuous with the first power supply connection hole PSCH1, and may penetrate the second interlayer insulating layer 123. Accordingly, the power supply connection hole PSCH including the first power supply connection hole PSCH1 and the second power supply connection hole PSCH2 may be prepared.

The second pad connection hole PDCH2 may be continuous with the first pad connection hole PDCH1, and may penetrate the second interlayer insulating layer 123 and the first interlayer insulating layer 122. Accordingly, the pad connection hole PDCH including the first pad connection hole PDCH1 and the second pad connection hole PDCH2 may be prepared.

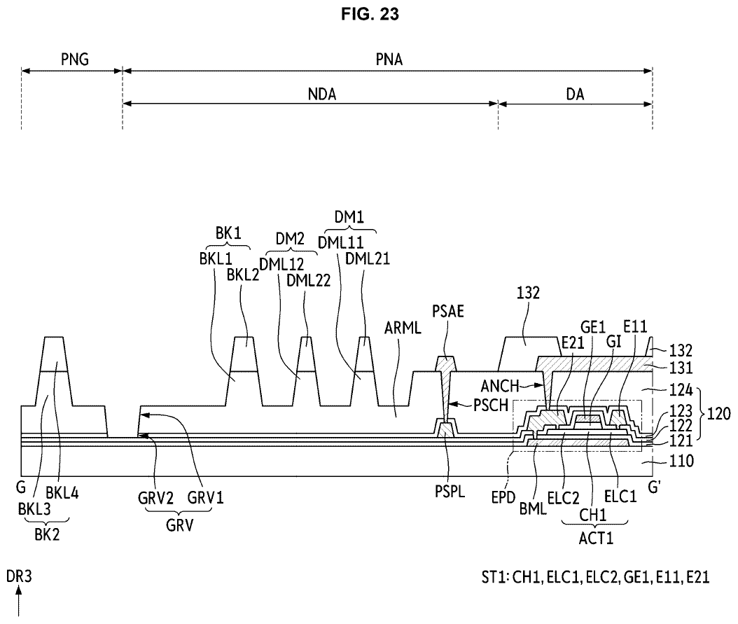

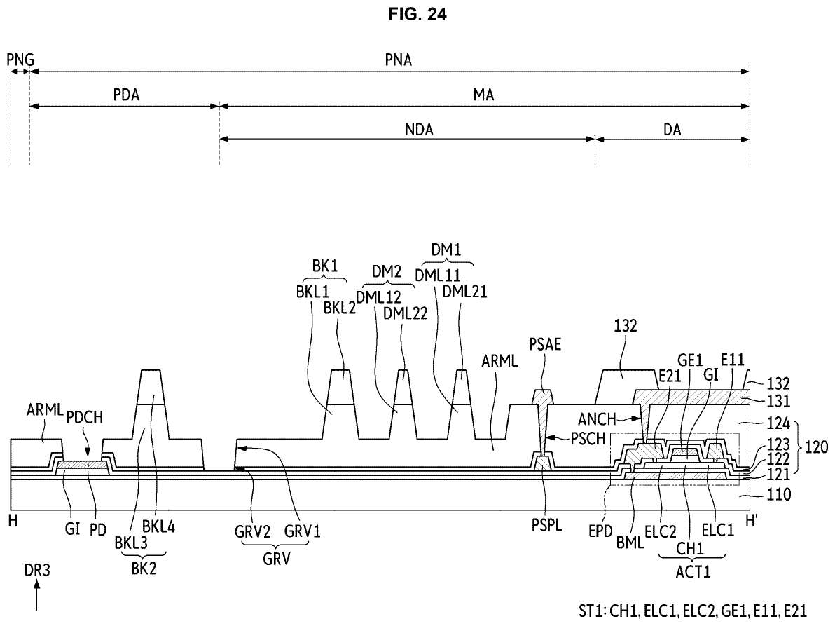

Referring to FIGS. 23 and 24, in the operation S141 of depositing the anode electrodes 131, a conductive material on the planarization layer 124 may be partially removed, so that the anode electrodes 131 may be located in the emission areas EA.

The anode electrode 131 may be electrically connected to the light-emitting pixel driver EPD through the anode connection hole ANCH.

In the operation S141 of depositing the anode electrodes 131, the power supply auxiliary electrode PSAE may be located in the non-display area NDA. The power supply auxiliary electrode PSAE may be electrically connected to the power supply line PSPL through the power supply connection hole PSCH.

In the operation S142 of depositing the pixel-defining layer 132, the organic insulating material covering the anode electrodes 131 may be partially removed, so that the pixel-defining layer 132 covering the edges of the anode electrodes 131 may be located in the display area DA.

In the operation S142 of depositing the pixel-defining layer 132, one or more second dam layers DML21 and DML22 may be located on one or more first dam layers DML11 and DML12.

In the operation S142 of depositing the pixel-defining layer 132, the second bank layer BKL2 may be located on the first bank layer BKL1, and the fourth bank layer BKL4 may be located on the third bank layer BKL3.

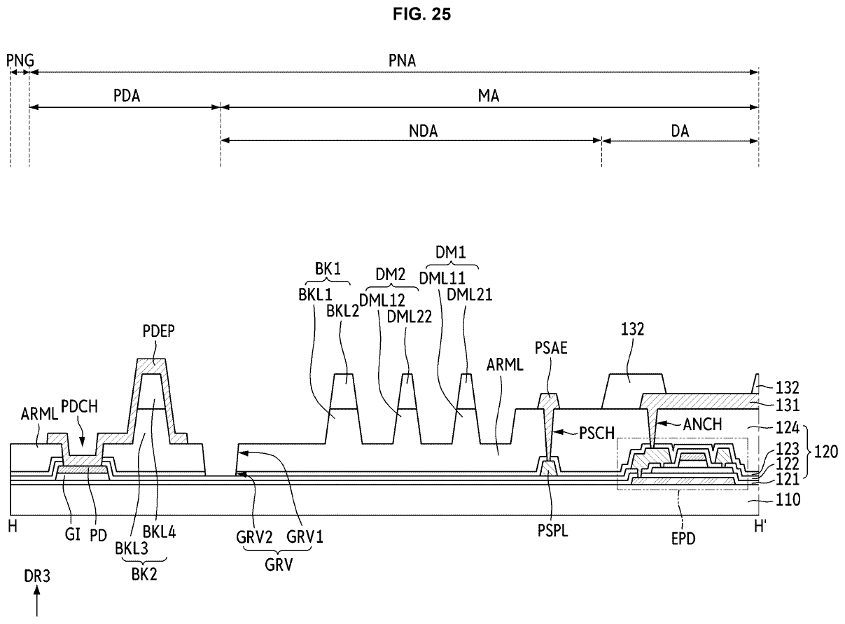

Referring to FIG. 25, in a method for manufacturing the display device 10 of other embodiments illustrated in FIGS. 10, 11, and 12, after the operation S142 of depositing the pixel-defining layer 132, depositing the pad extension portions PDEP may be further included.

The pad extension portions PDEP may overlap the third bank layer BKL3 and the fourth bank layer BKL4, and may respectively contact the pads PD through the first pad connection holes PDCH1 and the second pad connection holes PDCH2.

One of the pad extension portions PDEP may contact at least a portion of one of the pads PD.

Referring to FIGS. 26 and 27, in the operation S143 of depositing the light-emitting layer 133, an organic light-emitting material may be stacked on the display area DA, so that the light-emitting layer 133 may be located on the anode electrodes 131 and the pixel-defining layer 132.

At this time, in the operation S143 of depositing the light-emitting layer 133, the first mask MSK1 mounted on the second bank layer BKL2 may be used. The first mask MSK1 may include a first opening OP1 facing the display area DA, and a first mask support MSP1 opposing the second bank layer BKL2.

Alternatively, in the operation S143 of depositing the light-emitting layer 133, a mask including openings facing the emission areas EA1, EA2, and EA3 of the same color among the emission areas EA may be used.

In the operation S144 of depositing the cathode electrode 134, a conductive material is stacked in a state where the first mask MSK1 is placed on the second bank layer BKL2, so that the cathode electrode 134 may be located on the light-emitting layer 133.

Referring to FIGS. 28 and 29, the operation S150 of depositing the encapsulation layer 140 may include depositing the first encapsulation layer 141.

In the operation of depositing the first encapsulation layer 141, an inorganic insulating material is stacked in a state where the second mask MSK2 is placed on the fourth bank layer BKL4, so that the element layer 130, the auxiliary residual layer ARML, one or more second dam layers DML21 and DML22, and the first encapsulation layer 141 covering the second bank layer BKL2 may be located.

The second mask MSK2 may include a second opening OP2 facing the main region MA and a second mask support MSP2 opposing the fourth bank layer BKL4.

The first encapsulation layer 141 may be located entirely in the main region MA by the second opening OP2, and thus may cover the element layer 130, the auxiliary residual layer ARML, one or more second dam layers DML21 and DML22, and the second bank layer BKL2.

In addition, the first encapsulation layer 141 may contact the second interlayer insulating layer 123 or the first interlayer insulating layer 122 through the first groove GRV1 and the second groove GRV2.

Accordingly, the auxiliary residual layer ARML of the non-display area NDA and the planarization layer 124 of the display area DA may be sealed by inorganic bonding between the second interlayer insulating layer 123 or the first interlayer insulating layer 122 and the first encapsulation layer 141.

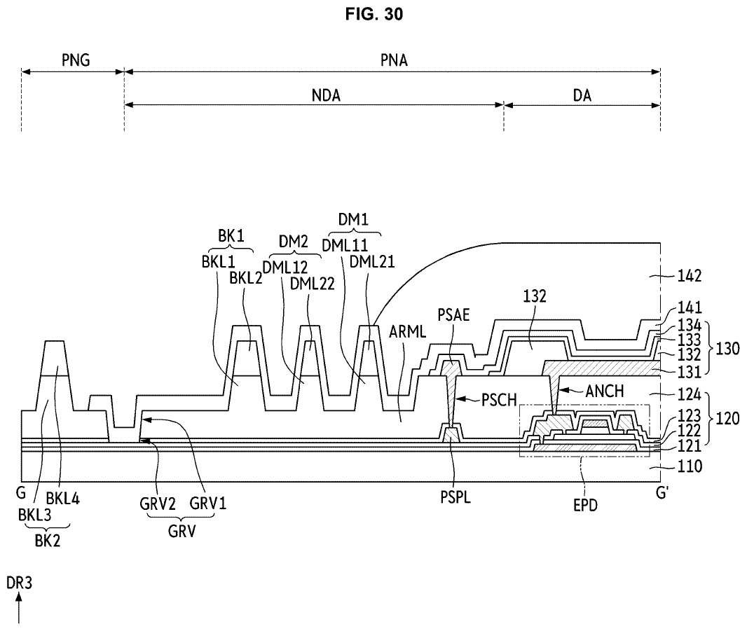

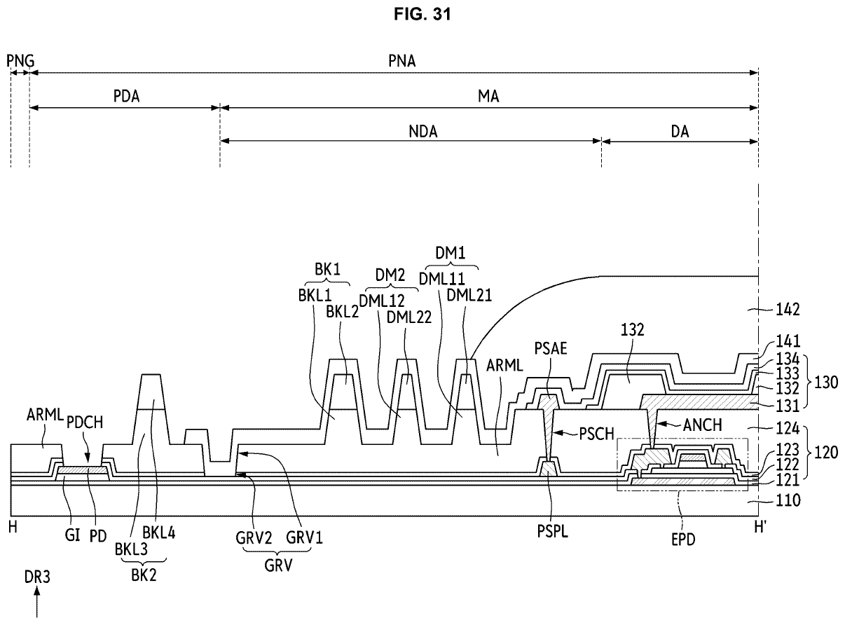

Referring to FIGS. 30 and 31, the operation S150 of depositing the encapsulation layer 140 may include depositing the second encapsulation layer 142 on the first encapsulation layer 141.

In the operation of depositing the second encapsulation layer 142, an organic insulating material dropped on the first encapsulation layer 141 of the display area DA may be diffused and cured, so that the second encapsulation layer 142 surrounded by one or more first dam layers DML11 and DML12 and one or more second dam layers DML21 and DML22 may be located.

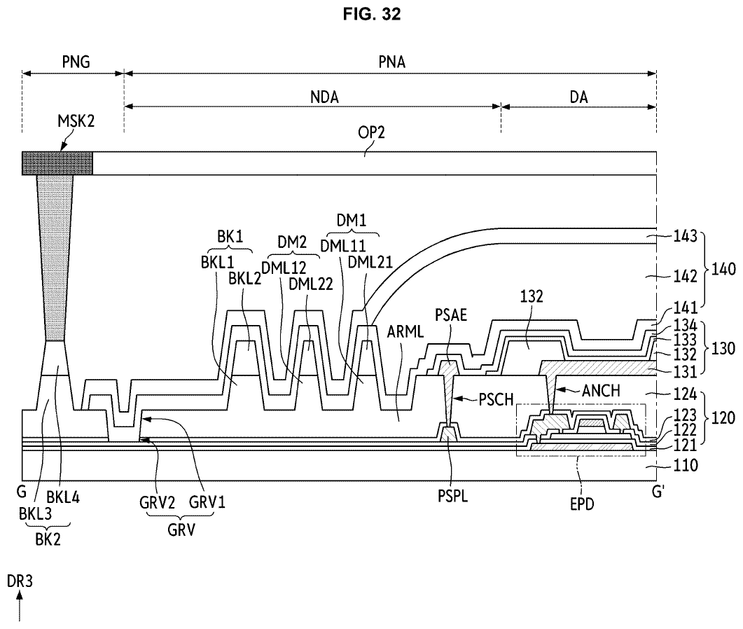

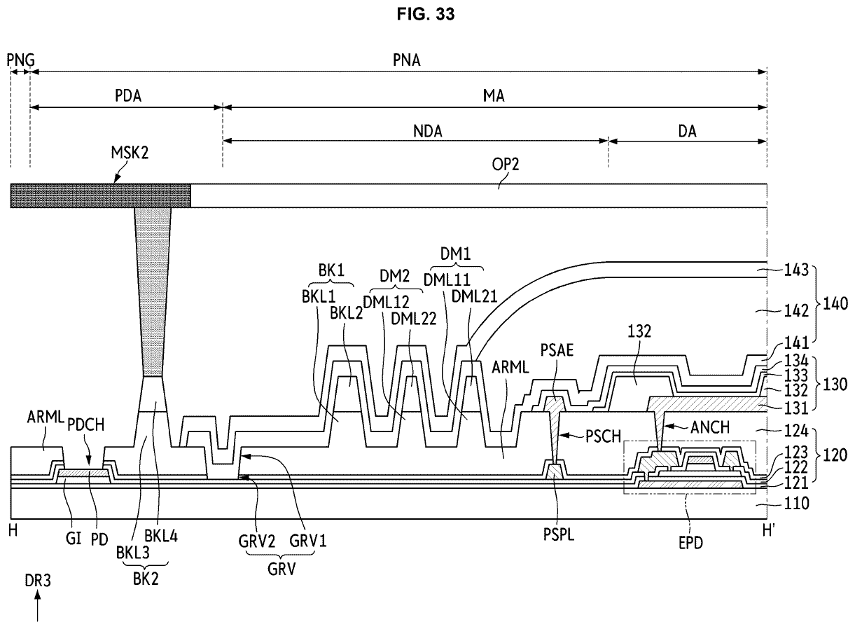

Referring to FIGS. 32 and 33, the operation S150 of depositing the encapsulation layer 140 may include depositing the third encapsulation layer 143 covering the second encapsulation layer 142.

In the operation of depositing the third encapsulation layer 143, an inorganic insulating material may be stacked in a state where the second mask MSK2 is placed on the fourth bank layer BKL4, so that the third encapsulation layer 143 covering the second encapsulation layer 142 may be located.

The third encapsulation layer 143 may be located entirely in the main region MA by the second opening OP2, and thus may contact the first encapsulation layer 141 around the one or more second dam layers DML21 and DML22, that is, at the edge of the main region MA.

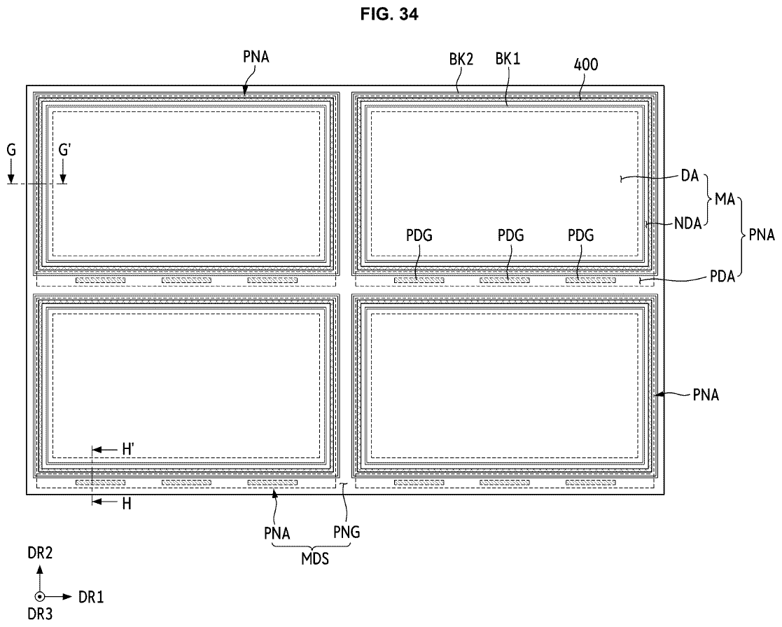

Referring to FIGS. 34, 35, and 36, after the color conversion layer 150 is located on the encapsulation layer 140, the sealing layer 400 may be located on the third encapsulation layer 143.

As illustrated in FIG. 24, in the operation S160 of depositing the sealing layer 400, the sealing layer 400 may be located in a closed curve shape surrounding the first bank BK1 in the non-display area NDA of each of the plurality of panel areas PNA.

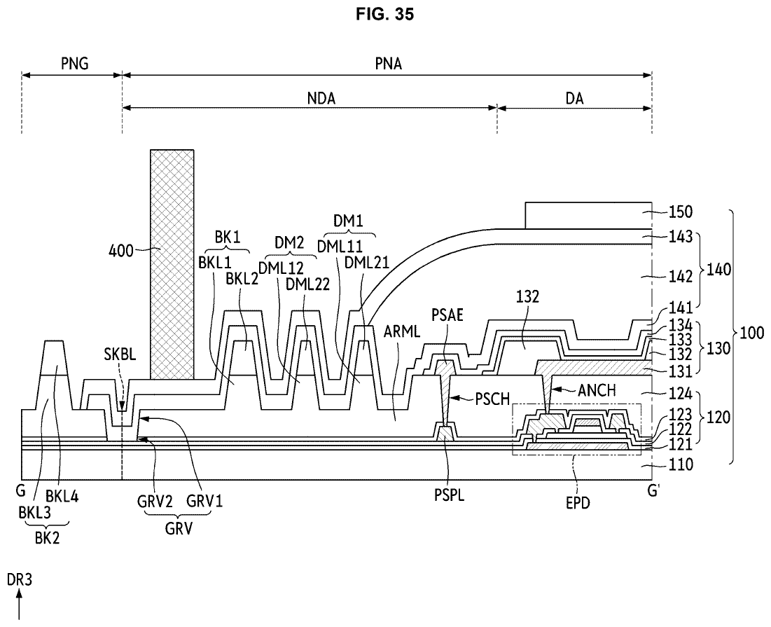

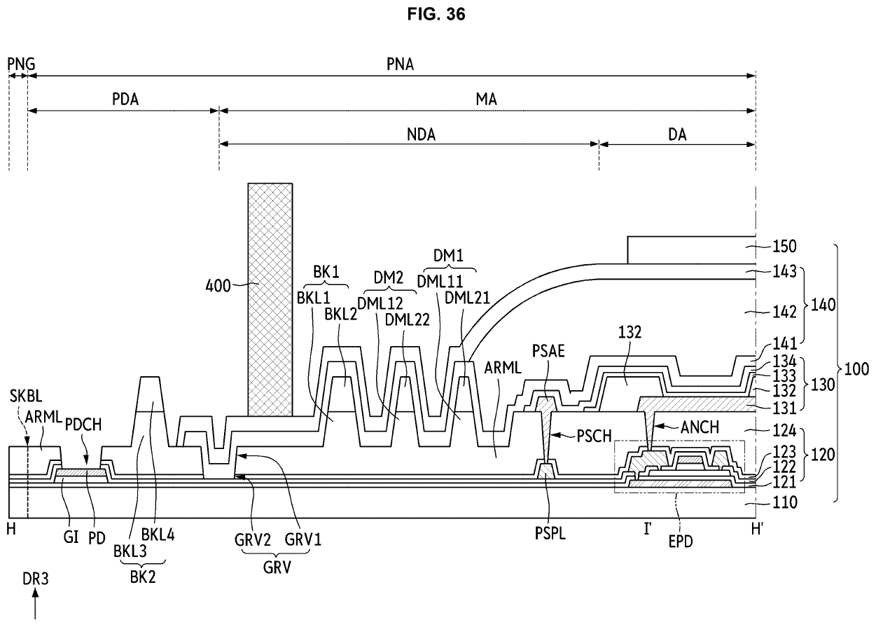

As illustrated in FIGS. 35 and 36, the sealing layer 400 may be located on the third encapsulation layer 143 in the non-display area NDA. Accordingly, regardless of the auxiliary residual layer ARML, the sealing layer 400 may be bonded to the third encapsulation layer 143, so that the likelihood of easy peeling of the sealing layer 400 may be reduced or prevented.

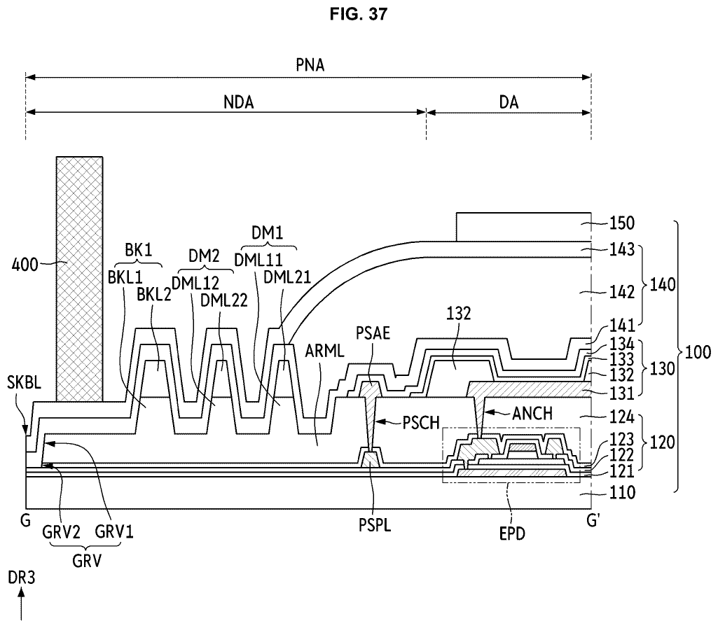

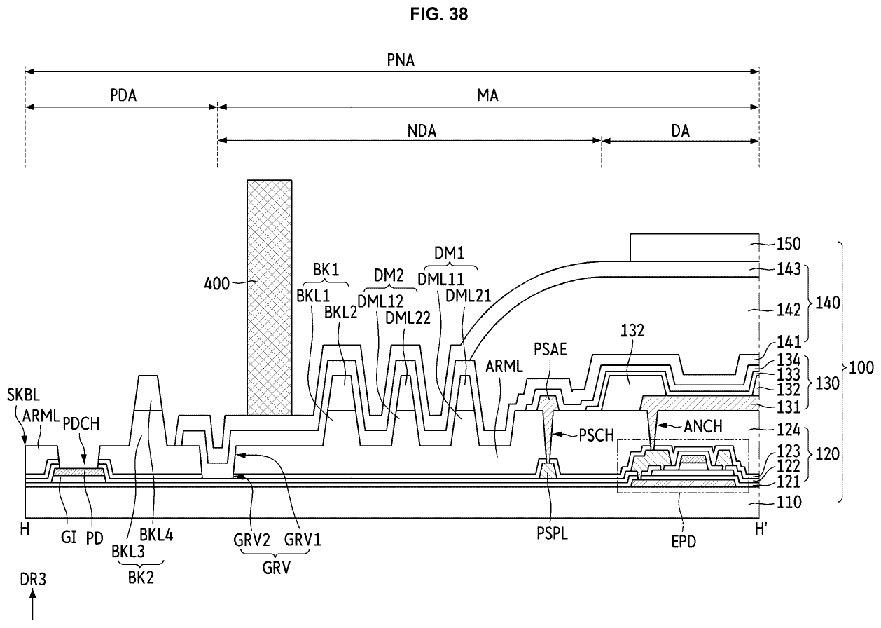

Referring to FIGS. 37 and 38, in the operation S20 of separating the plurality of first substrates 100, the mother substrate MDS may be separated by a scribing line SKBL, so that the plurality of first substrates 100 may be separated from each other. The scribing line SKBL may be an edge of the panel area PNA. Accordingly, the remaining portion of the first groove GRV1 except for a portion thereof located in the pad area PDA may overlap the scribing line SKBL.

As described above, according to embodiments, as the process of removing the auxiliary residual layer ARML is not included, it may be advantageous in streamlining the method for manufacturing the display device.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A display device comprising:
a first substrate comprising:
a first support substrate comprising:
a main region comprising a display area comprising emission areas arranged side by side, and a non-display area around the display area; and
a pad area connected to at least a portion of one side of the main region;
a circuit layer above the first support substrate;
a planarization layer above the circuit layer, comprising an organic insulating material, and in the display area;
an auxiliary residual layer in the non-display area and the pad area, extending from the planarization layer, and having a thickness that is less than that of the planarization layer;
an element layer above the planarization layer, in the display area, and comprising light-emitting elements in the emission areas; and
an encapsulation layer above the element layer;
a second substrate opposing the first substrate; and
a sealing layer between the first substrate and the second substrate in the non-display area to couple the first substrate to the second substrate.

2. The display device of claim 1, wherein the first substrate further comprises:
a first bank in the non-display area between an edge of the display area and the sealing layer in plan view; and
a second bank in the pad area, and extending parallel to one side of the main region,
wherein the first bank and the sealing layer are around the display area in plan view, and
wherein the first bank and the second bank are above the auxiliary residual layer.

3. The display device of claim 2, wherein the first substrate further comprises one or more dam portions comprising two or more dam layers comprising an organic insulating material in the non-display area above the auxiliary residual layer and between the edge of the display area and the first bank in plan view, and wherein the first bank and the second bank comprise two or more bank layers comprising an organic insulating material.

4. The display device of claim 3, wherein the element layer comprises:
anode electrodes in the emission areas;
a pixel-defining layer in a non-emission area between the emission areas, comprising an organic insulating material, and covering edges of the anode electrodes;
a light-emitting layer above the anode electrodes and the pixel-defining layer; and
a cathode electrode above the light-emitting layer.

5. The display device of claim 4, wherein the first bank comprises:
a first bank layer above the auxiliary residual layer; and
a second bank layer above the first bank layer,
wherein the second bank comprises:
a third bank layer above the auxiliary residual layer; and
a fourth bank layer above the third bank layer,
wherein the two or more dam layers comprise:
a first dam layer above the auxiliary residual layer; and
a second dam layer above the first dam layer,
wherein the auxiliary residual layer, the first bank layer, and the first dam layer are at a same layer as the planarization layer, and
wherein the second bank layer and the second dam layer are at a same layer as the pixel-defining layer.

6. The display device of claim 3, wherein the circuit layer comprises:
a buffer layer above the first support substrate;
a first interlayer insulating layer above the buffer layer; and
a second interlayer insulating layer above the first interlayer insulating layer,
wherein the buffer layer, the first interlayer insulating layer, and the second interlayer insulating layer comprise an inorganic insulating material,
wherein the planarization layer is above the second interlayer insulating layer, and
wherein the encapsulation layer comprises:
a first encapsulation layer above the element layer, comprising an inorganic insulating material, covering the one or more dam portions and the first bank, extending to the pad area, and adjacent to the second bank;
a second encapsulation layer above the first encapsulation layer in an area surrounded by the one or more dam portions, and comprising an organic insulating material; and
a third encapsulation layer covering the second encapsulation layer, comprising an inorganic insulating material, contacting the first encapsulation layer in a portion between an edge of the main region and the one or more dam portions in the non-display area, and contacting the first encapsulation layer in a portion between one side of the main region and the second bank in the pad area, and
wherein the sealing layer is above the third encapsulation layer.

7. The display device of claim 6, wherein the first substrate defines a groove extending along the edge of the main region, penetrating the auxiliary residual layer, and comprising a portion extending along one side of the main region between the sealing layer and the second bank, and
wherein the first encapsulation layer contacts the second interlayer insulating layer or the first interlayer insulating layer through the groove.

8. The display device of claim 7, wherein the circuit layer comprises:
light-emitting pixel drivers electrically connected to the light-emitting elements;
lines electrically connected to the light-emitting pixel drivers, and extending to the non-display area and the pad area; and
pads in the pad area, electrically connected to the lines, and covered by the second interlayer insulating layer and the auxiliary residual layer,
wherein the circuit layer defines pad connection holes respectively defined by the pads, and penetrating the second interlayer insulating layer and the auxiliary residual layer, and
wherein the second bank is between the groove and the pads in plan view.

9. The display device of claim 8, wherein the first substrate further comprises pad extension portions overlapping the second bank, and respectively contacting the pads through the pad connection holes.

10. The display device of claim 9, wherein one of the pad extension portions contacts at least a portion of one of the pads.

11. The display device of claim 3, wherein the emission areas comprise:
a first emission area for emitting light in a first wavelength band;
a second emission area for emitting light in a second wavelength band that is lower than the first wavelength band; and
a third emission area for emitting light in a third wavelength band that is lower than the second wavelength band,
wherein the light-emitting elements are configured to emit light in a fourth wavelength band that is lower than the third wavelength band,
wherein the first substrate further comprises:
a color conversion layer above the encapsulation layer for converting a wavelength band of the light emitted from some of the light-emitting elements; and
a color conversion capping layer covering the color conversion layer,
wherein the second substrate comprises:
a second support substrate comprising the main region;
a color filter layer on one surface of the second support substrate and facing the color conversion layer; and
a filter capping layer covering the color filter layer,
wherein the color conversion layer comprises:
a first color conversion portion in the first emission area for converting light in the fourth wavelength band into light in the first wavelength band;
a second color conversion portion in the second emission area for converting light in the fourth wavelength band into light in the second wavelength band;
a light-transmitting portion in the third emission area and transmitting for scattering light in the fourth wavelength band; and
a partition wall among the first color conversion portion, the second color conversion portion, and the light-transmitting portion, and
wherein the color filter layer comprises:
a first filter portion in the first emission area for transmitting light in the first wavelength band;
a second filter portion in the second emission area for transmitting light in the second wavelength band; and
a third filter portion in the third emission area for transmitting light in the third wavelength band; and
a light-blocking portion in a non-emission area between the emission areas for blocking light.

12. A method for manufacturing a display device, the method comprising:
preparing first substrates by using a mother substrate comprising panel areas comprising:
a main region comprising a display area comprising emission areas arranged side by side, and a non-display area around the display area; and
a pad area connected to at least a portion of one side of the main region;
separating the first substrates comprising first support substrates comprising portions of the mother substrate in the panel areas;
preparing a second substrate; and
bonding one of the first substrates to the second substrate,
wherein the preparing of the first substrates comprises:
depositing a circuit layer in the panel areas;
depositing a planarization layer in the display area by partially removing an organic insulating material covering the circuit layer;
depositing an auxiliary residual layer having a thickness that is less than that of the planarization layer in the non-display area and the pad area;
depositing an element layer on the planarization layer;
depositing an encapsulation layer on the element layer and the auxiliary residual layer; and
depositing a sealing layer in the non-display area of the panel areas.

13. The method of claim 12, wherein the depositing of the element layer comprises:
depositing anode electrodes in the emission areas;
depositing a pixel-defining layer covering edges of the anode electrodes in a non-emission area between the emission areas by partially removing an organic insulating material covering the anode electrodes;
depositing a light-emitting layer on the anode electrodes and the pixel-defining layer; and
depositing a cathode electrode on the light-emitting layer,
wherein the depositing the planarization layer and the depositing the auxiliary residual layer comprises depositing:
one or more first dam layers in the non-display area and sequentially surrounding an edge of the display area in plan view;
a first bank layer in the non-display area and surrounding the one or more first dam layers in plan view; and
a third bank layer having a portion surrounding remaining sides, excluding one side contacting the pad area, among edges of the main region, and a remaining portion in the pad area and surrounding one side of the main region,
wherein the depositing of the pixel-defining layer comprises depositing one or more second dam layers above the one or more first dam layers, a second bank layer above the first bank layer, and a fourth bank layer above the third bank layer, and
wherein depositing the cathode electrode comprises stacking a conductive material in a state where a first mask is above the second bank layer.

14. The method of claim 13, wherein the depositing of the circuit layer comprises depositing:
a buffer layer above the first support substrate;
a first interlayer insulating layer above the buffer layer; and
a second interlayer insulating layer above the first interlayer insulating layer,
wherein the planarization layer is above the second interlayer insulating layer,
wherein the planarization layer and the auxiliary residual layer define first anode connection holes overlapping the anode electrodes and penetrating the planarization layer, and
wherein the depositing of the element layer further comprises forming second anode connection holes that are continuous with the first anode connection holes and that penetrate the second interlayer insulating layer.

15. The method of claim 14, wherein the depositing of the planarization layer and the auxiliary residual layer comprises forming a first groove extending along an edge of the main region and penetrating the auxiliary residual layer, and
wherein the forming of the second anode connection holes comprises forming a second groove continuous with the first groove and penetrating the second interlayer insulating layer.

16. The method of claim 15, wherein the separating of the first substrates comprises separating the mother substrate using a scribing line, and
wherein a remaining portion of the first groove, excluding a portion in the pad area, overlaps the scribing line.

17. The method of claim 15, wherein the depositing of the encapsulation layer comprises:
depositing a first encapsulation layer contacting the second interlayer insulating layer or the first interlayer insulating layer through the first groove and the second groove, and covering the element layer, the auxiliary residual layer, the one or more second dam layers, and the second bank layer by stacking an inorganic insulating material in a state where a second mask is above the fourth bank layer;
depositing a second encapsulation layer surrounded by the one or more first dam layers and the one or more second dam layers in plan view by diffusing and curing an organic insulating material dropped on the first encapsulation layer of the display area; and
depositing a third encapsulation layer covering the second encapsulation layer by stacking an inorganic insulating material in a state where the second mask is above the fourth bank layer.

18. The method of claim 17, wherein the third encapsulation layer contacts the first encapsulation layer at the edge of the main region, and
wherein the sealing layer is above the third encapsulation layer.

19. An electronic device comprising a display device comprising:
a first substrate comprising:
a first support substrate comprising:
a main region comprising a display area comprising emission areas arranged side by side, and a non-display area around the display area; and
a pad area connected to at least a portion of one side of the main region;
a circuit layer above the first support substrate;
a planarization layer above the circuit layer, comprising an organic insulating material, and in the display area;
an auxiliary residual layer in the non-display area and the pad area, extending from the planarization layer, and having a thickness that is less than that of the planarization layer;
an element layer above the planarization layer, in the display area, and comprising light-emitting elements in the emission areas; and
an encapsulation layer above the element layer;
a second substrate opposing the first substrate; and
a sealing layer between the first substrate and the second substrate in the non-display area to couple the first substrate to the second substrate.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
